(19) United States
(12) Patent Application Publication
(10) Pub. No.: US 2022/0404204 A1
(43) Pub. Date: Dec. 22, 2022

(54) THERMOREFLECTANCE ENHANCEMENT COATINGS AND METHODS OF MAKING AND USE THEREOF

(71) Applicant: Georgia Tech Research Corporation, Atlanta, GA (US)

(72) Inventors: Riley Hanus, Atlanta, GA (US); Samuel Graham, Jr., Atlanta, GA (US)

(21) Appl. No.: 17/721,695

(22) Filed: Apr. 15, 2022

Related U.S. Application Data
(60) Provisional application No. 63/211,834, filed on Jun. 17, 2021.

(51) Int. Cl. G01J 5/00; G01N 21/17; H01L 21/02; G01J 5/80; G01N 21/55; G01J 5/08; C23C 14/06; C09D 5/26; C09D 7/65

(52) U.S. Cl. CPC G01J 5/0007; G01N 21/1717; H01L 21/02568; H01L 21/0226; H01L 21/02617; G01J 5/80; G01N 21/55; G01J 5/0896; C23C 14/0623; C09D 5/26; C09D 7/65; G01J 2005/0077; H01L 29/2003

(57) ABSTRACT

Disclosed herein are thermoreflectance enhancement coatings and methods of making and use thereof.

### CROSS-REFERENCE TO RELATED APPLICATIONS

This application claims the benefit of priority to U.S. Provisional Application No. 63/211,834 filed Jun. 17, 2021, which is hereby incorporated herein by reference in its entirety.

### STATEMENT OF GOVERNMENT SUPPORT

This invention was made with government support under Grant No. FA8075-14-D-0025 awarded by the Department of Defense. The government has certain rights in the invention.

### BACKGROUND

Thermoreflectance imaging is a powerful technique to yield high speed thermal imaging of objects. However, when the material or device being measured is transparent to the probe light, the surface temperature cannot he reliably measured. The compositions, methods, and systems discussed herein address these and other needs.

### SUMMARY

In accordance with the purposes of the disclosed compositions, methods, and systems as embodied and broadly described herein, the disclosed subject matter relates to electrically resistive films that are reflective to one or more wavelengths of light from 400 nm to 1500 nm, e.g., a thermoreflectance enhancement coating, and methods of making and use thereof.

Additional advantages of the disclosed compositions, systems, and methods will he set forth in part in the description which follows, and in part will be obvious from the description. The advantages of the disclosed compositions, systems, and methods will be realized and attained by means of the elements and combinations particularly pointed out in the appended claims. It is to be understood that both the foregoing general description and the following detailed description are exemplary and explanatory only and are not restrictive of the disclosed compositions, systems, and methods, as claimed.

The details of one or more embodiments of the invention are set forth in the accompanying drawings and the description below. Other features, objects, and advantages of the invention will be apparent from the description and drawings, and from the claims,

### BRIEF DESCRIPTION OF THE FIGURES

The accompanying figures, which are incorporated in and constitute a part of this specification, illustrate several aspects of the disclosure, and together with the description, serve to explain the principles of the disclosure.

FIG. 1. Band gap diagrams indicating that 530 nm light is reflective to Si and MoS₂. 365 nm light is close to the band gap of GaN so near band gap thermoreflectance imaging can be used to measure the surface temperature of GaN, 365 nm light is transparent to the most commonly used AlGaN compositions, including the one used in this study.

FIG. 2. GaN TLM device schematic. 530 nm light is transparent to the GaN, AlGaN, and AlN layers, but reflects off of the Si substrate. 365 nm light is near the band-gap of GaN, so the thermoreflectance signal comes from the GaN channel layer.

FIG. 3. AlGaN MOSHFET device schematic. Both 530 nm and 365 nm LEDs are transparent to the entire device. The only locations which provide a useable thermoreflectance signal without the MoS₂ coating are the source, gate and drain metal electrodes.

FIG. 4. GaN device with the MoS₂ coating. Electrical contact is made by puncturing the deposited MoS₂ coating. The red in indicates the hot spot location. The MoS₂ coating enables temperature mapping on the surface of the channel.

FIG. 5. AlGaN device with MoS₂ coating. The hot spot is located in the channel on the drain side of the gate metal. The MoS₂ coating enables temperature mapping on the surface of the channel.

FIG. 6. X-ray photoemission spectroscopy of the N o 3d and S 2s peaks.

FIG. 7. The Raman spectra of the MoS₂ film.

FIG. 8. Simulated structure showing XRD pattern of randomly oriented MoS₂ particles with an isotropic size of d=1 μm compared to the measured XRD and refinement model. We conclude that the coating has an orientation of larger than 77% in the 001 direction. The refined particle size in the 001 direction, obtained primarily from the broadening of the 002 peak, was d₀₀₁=19 nm.

FIG. 9. Atomic force microscopy (AFM) data measuring the uniformity of the MoS₂ coating. The histogram across a step edge of the coating (white arrow) is shown in the inset.

FIG. 10. Temperature dependent thermoreflectance of the MoS₂ coating on the GaN device. The error bars indicate the standard deviation of Cₜₕ over the region of interest between the source and drain in FIGS. 15-20.

FIG. 11. I_{DS} of AlGaN transistor. Open and filled circles indicate before and after the MoS₂ coating and annealing procedure, respectively.

FIG. 12. I_{GS} of the AlGaN transistor. Open and filled circles indicate before and after the MoS₂ coating and annealing procedure, respectively.

FIG. 13. I_{DS} of GaN TLM device. Open and filled circles indicate before and after MoS₂ coating and annealing procedure, respectively.

FIG. 14. Isolation leakage current testing showing no measurable increase in leakage current was observed. Open and filled circles indicate before and after the MoS₂ coating and annealing procedure, respectively.

FIG. 15. Thermal imaging of the GaN TLM structure, with a 20 μm source to drain spacing. CCD image of the device before coating.

FIG. 16. Thermal imaging of the, GaN TLM structure, with a 20 μm source to drain spacing. Temperature rise map measured using near band gap TTI, using and LED wavelength of λ=365 nm.

FIG. 17. Thermal imaging of the GaN TLM structure, with a 20 μm source to drain spacing. The temperature rise map obtained using a 530 nm LED without the MoS₂ coating.

FIG. 18. Thermal imaging of the GaN TLM structure, with a 20 μm source to drain spacing. CCD image of the device after MoS₂ coating (measured thickness given in top right corner).

FIG. 19. Thermal imaging of the, GaN TLM structure, with a 20 μm source to drain spacing. Temperature rise map measured using a 530 nm LED with the MoS₂ coating deposited.

FIG. 20. Thermal imaging of the GaN TLM structure, with a 20 μm source to drain spacing. The 1D temperature slices with start and ending positions indicated by the teal triangles in FIG. 16, FIG. 17, and FIG. 19. The uncoated data obtained using a 365 nm LED agrees with the MoS₂ coated data using a 530 nm LED, which provides validation for this technique.

FIG. 21. Cₜₕ map of the uncoated GaN TLM structure measured using a 365 nm LED.

FIG. 22. Histogram of Cₜₕ for the channel of the uncoated GaN TLM structure.

FIG. 23. Cₜₕ map of the coated GaN TLM structure measured using a 530 nm LED.

FIG. 24. Histogram of Cₜₕ of the coated GaN TLM structure.

FIG. 25. Transient pulse data.

FIG. 26. CCD image of the AlGaN MOSHFET device, with a gate to drain spacing 10 μm, before coating.

FIG. 27. Thermal imaging of the AlGaN MOSHFET, with a gate to drain spacing 10 μm. Temperature rise (ΔT) map measured using an LED wavelength of λ=530 nm.

FIG. 28. CCD image of the AlGaN MOSHFET device, with a gate to drain spacing 10 μm, after MoS₂ coating (measured thickness given in top right corner).

FIG. 29. Thermal imaging of the AlGaN MOSHFET, with a gate to drain spacing 10 μm. ΔT map measured using a 530 nm LED after deposition of the MoS₂ coating.

FIG. 30. Thermal imaging of the AlGaN MOSHFET, with a gate to drain spacing 10 μm. 1D ΔT slices before and after MoS₂ coating. The start and ending positions of the 1D slice are indicated by the teal stars in FIG. 27 and FIG. 29 (top-down in FIG. 27 and FIG. 29 corresponds to left-right in FIG. 30). The temperature on the gate metal before and after coating with MoS₂ agrees, which provides further validation for this technique. The MoS₂ coating enables the measurement of a maximum ΔT of 50 K which occurs within the channel near the drain side of the gate. This max ΔT is more than double the maximum temperature observed without the coating.

FIG. 31. 1D temperature rise scans (same scan location as FIG. 29) at different V_{DS} conditions.

FIG. 32. Thermal resistance of the uncoated AlGaN transistor measured on the gate metal compared to the thermal resistance measured using the MoS₂ coating on both the gate metal and at the peak channel temperature. The MoS₂ TTI enhancement coating enable the measurement of a thermal resistance that is over twice as large as that measured without the coating.

FIG. 33. Importance of measuring peak temperature for accelerated testing of power electronics. Acceleration factor (AF, unitless) for versus the activation energy of the primary degradation process (Eₐ) and the operating power assuming a device thermal resistance of 145 W/(mm K).

FIG. 34. Importance of measuring peak temperature for accelerated testing of power electronics. The same relationship as in FIG. 33 assuming a device thermal resistance of 345 W/(mm K).

FIG. 35: Chemical formula and structure of PE₂.

FIG. 36. CCD image of the PE₂ polymer film containing a scratch.

FIG. 37. The coefficient of thermoreflectance map Cₜₕ. The Cₜₕ in the scratch region is close to zero which indicates that the light is indeed reflecting from the PE₂ film.

FIG. 38. The Cₜₕ histogram of the region of interest designated by the red box in FIG. 36.

FIG. 39. The temperature dependence of ΔR/R. The linearity demonstrates a constant Cₜₕ value across a sufficiently large temperature range.

FIG. 40. 20 μm TLM is shown up and to the right of the “+” sign.

FIG. 41. Pulse information.

FIG. 42. Temperature calibration at 100° C.

FIG. 43. Temperature calibration at 70° C.

FIG. 44. Temperature calibration at 60° C.

FIG. 45. Temperature calibration at 50° C.

FIG. 46. Thermal imaging of device #1 (uncoated).

FIG. 47. Thermal imaging of device #2 (uncoated).

FIG. 48. Thermal imaging of device #3 (uncoated).

FIG. 49. Photograph of the solutions used to coat the devices. Molylube, Sonal MoS₂/IPA/Tp, and Sonal MoS₂/IPA in vials left to right.

FIG. 50. TTI of sample coated with Molylube.

FIG. 51. A plot of ΔR/R vs. T.

### DETAILED DESCRIPTION

The compositions, methods, and systems described herein may be understood more readily by reference to the following detailed description of specific aspects of the disclosed subject matter and the Examples included therein.

Before the present compositions, methods, and systems are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

In this specification and in the claims that follow, reference will be made to a number of terms, which shall be defined to have the following meanings.

Throughout the description and claims of this specification the word “comprise” and other forms of the word, such as “comprising” and “comprises,” means including but not limited to, and is not intended to exclude, for example, other additives, components, integers, or steps.

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such components, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. By “about” is meant within 5% of the value, e.g., within 4, 3, 2, or 1% of the value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Values can be expressed herein as an “average” value. “Average” generally refers to the statistical mean value.

By “substantially” is meant within 5%, e.g., within 4%, 3%, 2%, or 1%.

“Exemplary” means “an example of” and is not intended to convey an indication of a preferred or ideal embodiment. “Such as” is not used in a restrictive sense, but for explanatory purposes.

It is understood that throughout this specification the identifiers “first” and “second” are used solely to aid in distinguishing the various components and steps of the disclosed subject matter. The identifiers “first” and “second” are not intended to imply any particular order, amount, preference, or importance to the components or steps modified by these terms.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

Disclosed herein are electrically resistive films that are reflective to one or more wavelengths of light from 400 nm to 1500 nm, e.g., thermoreflectance enhancement coatings, and methods of making and use thereof.

For example, the coating can be reflective to light having one or more wavelengths of 400 nanometers (nm) or more (e.g., 405 nm or more, 410 nm or more, 415 nm or more, 420 nm or more, 425 nm or more, 430 nm or more, 435 nm or more, 440 nm or more, 445 nm or more, 450 nm or more, 455 nm or more, 460 nm or more, 465 nm or more, 470 nm or more, 475 nm or more, 480 nm or more, 485 nm or more, 490 nm or more, 495 nm or more, 500 nm or more, 505 nm or more, 510 nm or more, 515 nm or more, 520 nm or more, 525 nm or more, 530 nm or more 535 nm or more, 540 nm or more, 545 nm or more, 550 nm or more, 555 nm or more, 560 nm or more, 565 nm or more, 570 nm or more, 575 nm or more, 580 nm or more, 585 nm or more, 590 nm or more, 595 nm or more, 600 nm or more, 605 nm or more, 610 nm or more, 615 nm or more, 620 nm or more, 625 nm or more, 630 nm or more, 635 nm or more, 640 nm or more, 645 nm or more, 650 nm or more, 655 nm or more, 660 nm or more, 665 nm or more, 670 nm or more, 675 nm or more, 680 nm or more, 685 nm or more, 690 nm or more, 695 nm or more, 700 nm or more, 705 nm or more, 710 nm or more, 715 nm or more, 720 nm or more, 725 nm or more, 730 nm or more, 735 nm or more, 740 nm or more, 745 nm or more, 750 nm or more, 755 nm or more, 760 nm or more, 765 nm or more, 770 nm or more, 775 nm or more, 780 nm or more, 785 nm or more, 790 nm or more, 795 nm or more, 800 nm or more, 805 nm or more, 810 nm or more, 815 nm or more, 820 nm or more, 825 nm or more, 830 nm or more, 835 nm or more, 840 nm or more, 845 nm or more, 850 nm or more, 855 nm or more, 860 nm or more, 865 nm or more, 870 nm or more, 875 nm or more, 880 nm or more, 885 nm or more, 890 nm or more, 895 nm or more, 900 nm or more, 905 nm or more, 910 nm or more, 915 nm or more, 920 nm or more, 925 nm or more, 930 nm or more, 935 nm or more, 940 nm or more, 945 nm or more, 950 nm or more, 955 nm or more, 960 nm or more, 965 nm or more, 970 nm or more, 975 nm or more, 980 nm or more, 985 nm or more, 990 nm or more, 995 nm or more, 1000 nm or more, 1005 nm or more, 1010 nm or more, 1015 nm or more, 1020 nm or more, 1025 nm or more, 1030 nm or more, 1035 nm or more, 1040 nm or more, 1045 nm or more, 1050 nm or more, 1055 nm or more, 1060 nm or more, 1065 nm or more, 1070 nm or more, 1075 nm or more, 1080 nm or more, 1085 nm or more, 1090 nm or more, 1095 nm or more, 1100 nm or more, 1105 nm or more, 1110 nm or more, 1115 nm or more, 1120 nm or more, 1125 nm or more, 1130 nm or more, 1135 nm or more, 1140 nm or more, 1145 nm or more, 1150 nm or more, 1155 nm or more, 1160 nm or more, 1165 nm or more, 1170 nm or more, 1175 nm or more, 1180 nm or more, 1185 nm or more, 1190 nm or more, 1195 nm or more, 1200 nm or more, 1205 nm or more, 1210 nm or more, 1215 nm or more, 1220 nm or more, 1225 nm or more, 1230 nm or more, 1235 nm or more, 1240 nm or more, 1245 nm or more, 1250 nm or more, 1255 nm or more, 1260 nm or more, 1265 nm or more, 1270 nm or more, 1275 nm or more, 1280 nm or more, 1285 nm or more, 1290 nm or more, 1295 nm or more, 1300 nm or more, 1305 nm or more, 1310 nm or more, 1315 nm or more, 1320 nm or more, 1325 nm or more, 1330 nm or more, 1335 nm or more, 1340 nm or more, 1345 nm or more, 1350 nm or more, 1355 nm or more, 1360 nm or more, 1365 nm or more, 1370 nm or more, 1375 nm or more, 1380 nm or more, 1385 nm or more, 1390 nm or more, 1395 nm or more, 1400 nm or more, 1405 nm or more, 1410 nm or more, 1415 nm or more, 1420 nm or more, 1425 nm or more, 1430 nm or more, 1435 nm or more, 1440 nm or more, 1445 nm or more, 1450 nm or more, 1455 nm or more, 1460 nm or more, 1465 nm or more, 1470 nm or more, 1475 nm or more, 1480 nm or more, 1485 nm or more, 1490 nm or more, or 1495 nm or more).

In some examples, the coating can be reflective to light having one or more wavelengths of 1500 nanometers (am) or less (e,g., 1495 nm or less, 1490 nm or less, 1485 nm or less, 1480 nm or less, 1475 nm or less, 1470 nm or less, 1465 am or less, 1460 nm or less, 1455 nm or less, 1450 nm or less, 1445 nm or less, 1440 nm or less, 1435 nm or less, 1430 nm or less, 1425 nm or less, 1420 nm or less, 1415 nm or less, 1410 nm or less, 1405 nm or less, 1400 nm or less, 1395 nm or less, 1390 nm or less, 1385 nm or less, 1380 nm or less, 1375 nm or less, 1370 nm or less, 1365 nm or less, 1360 nm or less, 1355 nm or less, 1350 nm or less, 1345 nm or less, 1340 nm or less, 1335 nm or less, 1330 nm or less, 1325 nm or less, 1320 nm or less, 1315 nm or less, 1310 nm or less, 1305 nm or less, 1300 nm or less, 1295 nm or less, 1290 nm or less, 1285 nm or less, 1280 nm or less, 1275 nm or less, 1270 nm or less, 1265 nm or less, 1260 nm or less, 1255 nm or less, 1250 nm or less, 1245 nm or less, 1240 nm or less, 1235 nm or less, 1230 nm or less, 1225 nm or less, 1220 nm or less, 1215 nm or less, 1210 nm or less, 1205 nm or less, 1200 nm or less, 1195 nm or less, 1190 nm or less, 1185 nm or less, 1180 nm or less, 1175 nm or less, 1170 nm or less, 1165 nm or less, 1160 nm or less, 1155 nm or less, 1150 nm or less, 1145 nm or less, 1140 nm or less, 1135 nm or less, 1130 nm or less, 1125 nm or less, 1120 nm or less, 1115 nm or less, 1110 nm or less, 1105 nm or less, 1100 nm or less, 1095 nm or less, 1090 nm or less, 1085 nm or less, 1080 nm or less, 1075 nm or less, 1070 nm or less, 1065 nm or less, 1060 nm or less, 1055 nm or less, 1050 nm or less, 1045 nm or less, 1040 nm or less, 1035 nm or less, 1030 nm or less, 1025 nm or less, 1020 nm or less, 1015 nm or less, 1010 nm or less, 1005 nm or less, 1000 nm or less, 995 nm or less, 990 nm or less, 985 nm or less, 980 nm or less, 975 nm or less, 970 nm or less, 965 nm or less, 960 nm or less, 955 nm or less, 950 nm or less, 945 nm or less, 940 nm or less, 935 nm or less, 930 nm or less, 925 nm or less, 920 nm or less, 915 nm or less, 910 nm or less, 905 nm or less, 900 nm or less, 895 nm or less, 890 nm or less, 885 nm or less, 880 nm or less, 875 nm or less, 870 nm or less, 865 nm or less, 860 nm or less, 855 nm or less, 850 nm or less, 845 nm or less, 840 nm or less, 835 nm or less, 830 nm or less, 825 nm or less, 820 nm or less, 815 nm or less, 810 nm or less, 805 nm or less, 800 nm or less, 795 nm or less, 790 nm or less, 785 nm or less, 780 nm or less, 775 nm or less, 770 nm or less, 765 nm or less, 760 nm or less, 755 nm or less, 750 nm or less, 745 nm or less, 740 nm or less, 735 nm or less, 730 nm or less, 725 nm or less, 720 nm or less, 715 nm or less, 710 nm or less, 705 nm or less, 700 nm or less, 695 nm or less, 690 nm or less, 685 nm or less, 680 nm or less, 675 nm or less, 670 nm or less, 665 nm or less, 660 nm or less, 655 nm or less, 650 nm or less, 645 nm or less, 640 nm or less, 635 nm or less, 630 nm or less, 625 nm or less, 620 nm or less, 615 nm or less, 610 nm or less, 605 nm or less, 600 nm or less, 595 nm or less, 590 nm or less, 585 nm or less, 580 nm or less, 575 nm or less, 570 nm or less, 565 nm or less, 560 nm or less, 555 nm or less, 550 nm or less, 545 nm or less, 540 nm or less, 535 nm or less, 530 nm or less, 525 nm or less, 520 nm or less, 515 nm or less, 510 nm or less, 505 nm or less, 500 nm or less, 495 nm or less, 490 nm or less, 485 nm or less, 480 nm or less, 475 nm or less, 470 nm or less, 465 nm or less, 460 nm or less, 455 nm or less, 450 nm or less, 445 nm or less, 440 nm or less, 435 nm or less, 430 nm or less, 425 nm or less, 420 nm or less, 415 nm or less, 410 nm or less, or 405 nm or less).

The one or more wavelengths of light reflected by the coating can range from any of the minimum values described above to any of the maximum values described above. For example, the coating can be reflective to light having one or more wavelengths from 400 nm to 1500 nm (e.g., from 400 to 950 nm, from 950 nm to 1500 nm, from 400 nm to 500 nm, from 500 nm to 600 nm, from 600 nm to 700 nm, from 700 nm to 800 nm, from 800 nm to 900 nm, from 900 nm to 1000 nm, from 1000 nm to 1100 nm, from 1100 nm to 1200 nm, from 1200 nm to 1300 nm, from 1300 nm to 1400 nm, from 1400 nm to 1500 nm, from 400 nm to 1400 nm, from 400 nm to 1300 nm, from 400 nm to 1200 nm, from 400 nm to 1100 nm, from 400 nm to 1000 nm, from 400 nm to 900 nm, from 400 nm to 800 nm, from 400 nm to 700 nm, from 400 nm to 600 nm, from 500 nm to 1500 nm, from 600 nm to 1500 nm, from 700 nm to 1500 nm, from 800 nm to 1500 nm, from 900 nm to 1500 nm, from 1000 nm to 1500 nm, from 1100 nm to 1500 nm, from 1200 nm to 1500 nm, from 1300 nm to 1500 nm, from 500 nm to 1400 nm, from 600 nm to 1300 nm, from 500 nm to 1200 nm, from 600 nm to 1100 nm, or from 700 nm to 1000 nm).

The thermoreflectance enhancement coatings can, for example, comprise a transition metal dichalcogenide or a thermochromic polymer.

As used herein, a “transition metal dichalcogenide” refers to a compound comprising a transition metal and two chalcogen atoms. As used herein, a “transition metal” refers to any element from groups 3-12, such as Sc, Ti, V, Cr, Mn, Fe, Co, Ni, Cu, Zn, Y, Zr, Nb, Mo, Tc, Ru, Rh, Pd, Ag, Cd, La, Hf, Ta, W, Re, Os, Ir, Pt, Au, Hg, and Ac. As used herein a “chalcogen” refers to any element from group 16, such as oxygen, sulfur, selenium, tellurium, and polonium. As such, transition metal chalcogenides can include transition metal oxides, transition metal sulfides, and transition metal selenides, among others. For example, the transition metal dichalcogenide can comprise MoS₂, WS₂, MoSe₂, WSe₂, MoTe₂, WTe₂, or a combination thereof. In some examples, the transition metal dichalcogenide comprises MoS₂, MoSe₂, WS₂, WSe₂, or a combination thereof. In some examples, the transition metal dichalcogenide comprises MoS₂.

As used herein a “thermochromic polymer” can comprise any polymer with thermochromic properties. Thermochromic properties can, for example, include control of optical properties such as optical transmission, absorption, reflectance, and/or emittance in a continual manner on application of a temperature. In some examples, the thermochromic polymer can comprise poly(ProDOT-alt-EDOT₂) (PE₂).

The coating can, for example, have an average thickness of 10 nm or more (e.g., 15 nm or more, 20 nm or more, 25 nm or more, 30 nm or more, 35 nm or more, 40 nm or more, 45 nm or more, 50 nm or more, 60 nm or more, 70 nm or more, 80 nm or more, 90 nm or more, 100 nm or more, 125 nm or more, 150 nm or more, 175 nm or more, 200 nm or more, 225 nm or more, 250 nm or more, 275 nm or more, 300 nm or more, 325 nm or more, 350 nm or more, 400 nm or more, 450 nm or more, 500 nm or more, 550 nm or more, 600 nm or more, 650 nm or more, 700 nm or more, 750 nm or more, 800 nm or more, 850 nm or more, 900 nm or more, or 950 or more). In some examples, the coating can have an average thickness of 1000 nm or less (e.g., 950 nm or less, 900 nm or less, 850 nm or less, 800 nm or less, 750 nm or less, 700 nm or less, 650 nm or less, 600 nm or less, 550 nm or less, 500 nm or less, 450 nm or less, 400 nm or less, 350 nm or less, 325 nm or less, 300 nm or less, 275 nm or less, 250 nm or less, 225 nm or less, 200 nm or less, 175 nm or less, 150 nm or less, 125 nm or less, 100 nm or less, 90 nm or less, 80 nm or less, 70 nm or less, 60 nm or less, 50 nm or less, 45 nm or less, 40 nm or less, 35 nm or less, 30 nm or less, 25 nm or less, 20 nm or less, or 15 nm or less). The average thickness of the coating can range from any of the minimum values described above to any of the maximum values described above. For example, the coating can have an average thickness of 10 nm to 1000 nm (e.g., from 10 nm to 500 nm, from 500 nm to 1000 nm, from 10 nm to 200 nm, from 200 nm to 400 nm, from 400 nm to 600 nm, from 600 nm to 800 nm, from 800 nm to 1000 nm, from 25 nm to 1000 nm, from 10 nm to 900 nm, from 25 nm to 900 nm, or from 200 nm to 350 nm). Average thickness” and “mean thickness” are used interchangeably herein. Average thickness can be measured using methods known in the art, such as evaluation by profilometry, cross-sectional electron microscopy, atomic force microscopy (AFM), ellipsometry, or combinations thereof.

In some examples, the coating has an average coefficient of thermoreflectance (Cₜₕ) of −2×10⁻⁴ K⁻¹ or less (e.g., −2.05×10⁻⁴ K⁻¹ or less, −2.1×10⁻⁴ K⁻¹ or less, −2.15×10⁻⁴ K⁻¹ or less, −2.2×10⁻⁴ K⁻¹ or less, −2.25×10⁻⁴ K⁻¹ or less, −2.3×10⁻⁴ K⁻¹ or less, −2.35×10⁻⁴ K⁻¹ or less, −2.4×10⁻⁴ or less, −2.45×10⁻⁴ K⁻¹ or less, −2.5×10⁻⁴ K⁻¹ or less, −2.55×10⁻⁴ K⁻¹ or less, −2.6×10⁻⁴ K⁻¹ or less, −2.65×10⁻⁴ K⁻¹ or less, −2.7×10⁻⁴ K⁻¹ or less, −2.75×10⁻⁴ K⁻¹ or less, −2.8×10⁻⁴ K⁻¹ or less, −2.85×10⁻⁴ K⁻¹ or less, −2.9×10⁻⁴ K⁻¹ or less, −3×10⁻⁴ K⁻¹ or less, −3.1×10⁻⁴ K⁻¹ or less, −3.2×10⁻⁴ K⁻¹ or less, −3.3×10⁻⁴ K⁻¹ or less, −3.4×10⁻⁴ K⁻¹ or less, −3.5×10⁻⁴ K⁻¹ or less, −3.6×10⁻⁴ K⁻¹ or less, −3.7×10⁻⁴ K⁻¹ or less, −3,8×10⁻⁴ K⁻¹ or less, −3.9×10⁻⁴ K⁻¹ or less, −4×10⁻⁴K⁻¹ or less, −4.1×10⁻⁴ K⁻¹ or less, −4.2×10⁻⁴ K⁻¹ or less, −4.3×10⁻⁴ K⁻¹ or less, −4.4×10⁻⁴ K⁻¹ or less, −4.5×10⁻⁴ K⁻¹ or less, −4,6×10⁻⁴ K⁻¹ or less, −4.7×10⁻⁴ K⁻¹ or less, −4.8×10⁻⁴ K⁻¹ or less, −4.9×10⁻⁴ K⁻¹ or less, or −5×10⁻⁴ K⁻¹ or less) over a temperature range (ΔT) of 10 K or more (e.g., 20 K or more, 30 K or more. 40 K or more, 50 K or more, 60 K or more, 70 K or more, 80 K or more, 90 K or more, or 100 K or more).

In some examples, the coating has an average coefficient of thermoreflectance (Cₜₕ) with an absolute value of (|Cₜₕ|) 2×10⁻⁴ K⁻¹ or more (e.g., 2.05×10⁻⁴ K⁻¹ or more, 2.1×10⁻⁴ K⁻¹ or more, 2.15×10⁻⁴ K⁻¹ or more, 2.2×10⁻⁴ K⁻¹ or more. 2.25×10⁻⁴ K⁻¹ or more. 2.3×10⁻⁴ K⁻¹ or more, 2.35×10⁻⁴ K⁻¹ or more, 2.4×10⁻⁴K⁻¹ or more, 2.45×10⁻⁴ K⁻¹ or more, 2.5×10⁻⁴K⁻¹ or more, 2.55×10⁻⁴ K⁻¹ or more, 2.6×10⁻⁴ K⁻¹ or more, 2.65×10⁻⁴ K⁻¹ or more, 2.7×10⁻⁴ K⁻¹ or more, 2.75×10⁻⁴ K⁻¹ or more, 2.8×10⁻⁴ K⁻¹ or more, 2.85×10⁻⁴ K⁻¹ or more, 2.9×10⁻⁴ K⁻¹ or more, 2.95×10⁻⁴ K⁻¹ or more. 3×10⁻⁴ K⁻¹ or more, 3.1×10⁻⁴ K⁻¹ or more, 3.2×10⁻⁴ K⁻¹ or more, 3.3×10⁻⁴ K⁻¹ or more, 3.4×10⁻⁴ K⁻¹ or more, 3.5×10⁻⁴ K⁻¹ or more, 3.6×10⁻⁴ K⁻¹ or more, 3.7×10⁻⁴ K⁻¹ or more, 3.8×10⁻⁴ K⁻¹ or more. 3.9×10⁻⁴ K⁻¹ or more, 4×10⁻⁴ K⁻¹ or more, 4.1×10⁻⁴ K⁻¹ or more, 4.2×10⁻⁴ K⁻¹ or more, 4.3×10⁻⁴ K⁻¹ or more, 4.4×10⁻⁴ K⁻¹ or more, 4.5×10⁻⁴ K⁻¹ or more, 4.6×10⁻⁴ K⁻¹ or more. 4.7×10⁻⁴ K⁻¹ or more. 4.8×10⁻⁴ K⁻¹ or more, 4.9×10⁻⁴ K⁻¹ or more, or 5×10⁻⁴ K⁻¹ or more) over a temperature range (ΔT) of 10 K or more (e.g., 20 K or more, 30 K or more, 40 K or more, 50 K or more, 60 K or more, 70 K or more, 80 K or more, 90 K or more, or 100 K or more).

Also disclosed herein are methods of enhancing the thermoreflectance of a wide bandgap semiconductor, the method comprising depositing any of the coatings disclosed herein onto the wide bandgap semiconductor.

Depositing the coating can, for example, comprise printing (e.g., air jet printing, ink jet printing), electroplating, lithographic deposition, electron beam deposition, thermal deposition, spin coaling, drop-casting, zone casting, dip coating, blade coating, spraying, vacuum filtration, slot die coating, curtain coating, chemical vapor deposition (CVD), atomic layer deposition (ALD), physical vapor deposition (PVD), sputtering, pulsed layer deposition, molecular beam epitaxy, evaporation, or combinations thereof. In some examples, depositing the coating comprises printing, spin coating, sputtering, electron beam deposition, drop-casting, or a combination thereof.

In some examples, the methods can further comprise forming a solution comprising a solvent and the transition metal dichalcogenide or thermochromic polymer, and depositing the mixture to form the coating.

Examples of solvents include, but are not limited to, water, tetrahydrofuran (THF), N-methyl-2-pyrrolidone (NMP), dimethylformamide (DMF) N-methylformamide, formamide, ethylene glycol, polyethylene glycol, glycerol, alkane diol, ethanol, methanol, propanol, isopropanol, acetonitrile, acetone, tetraglyme, propylene carbonate, diglyme, dimethyl sulfoxide (DMSO), dimethoxyethane, dimethylacetamide, and combinations thereof.

In some examples, forming the solution can comprise dispersing the transition metal dichalcogenide or thermochromic polymer in the solvent. Dispersing the transition metal dichalcogenide or thermochromic polymer in the solvent can be accomplished by mechanical agitation, for example, mechanical stirring, shaking, vortexing, sonication (e.g., bath sonication, probe sonication, ultrasonication), and the like, or combinations thereof.

In some examples, the methods can further comprise drying the coating after deposition (e.g., air drying, spin drying, oven drying, vacuum drying, etc.).

Also disclosed herein are devices comprising a wide bandgap or ultrawide bandgap semiconductor, wherein the device further comprises the any of the thermoreflectance enhancement coatings disclosed herein deposited on the wide bandgap or ultrawide bandgap semiconductor. In some examples, the thermoreflectance enhancement coating does not significantly impact the operation of the device.

Also disclosed herein are methods of thermally imaging a wide bandgap or ultrawide bandgap semiconductor, the method comprising depositing any of the thermoreflectance enhancement coatings disclosed herein on the wide bandgap or ultrawide bandgap semiconductor and then thermally imaging the coating. Thermally imaging the coating can, for example, comprise using transient thermoreflectance imaging. In some examples, the method of thermal imaging can use a probe light having a wavelength below the bandgap of the semiconductor and being reflective to the coating. In some examples, the thermoreflectance coating can be removed from the device after thermal imaging and before use of the device.

A number of embodiments of the invention have been described. Nevertheless, it will be understood that various modifications may be made without departing from the spirit and scope of the invention. Accordingly, other embodiments are within the scope of the following claims.

The examples below are intended to further illustrate certain aspects of the systems and methods described herein, and are not intended to limit the scope of the claims.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in ° C. or is at ambient temperature, and pressure is at or near atmospheric. There are numerous variations and combinations of measurement conditions, e.g., component concentrations, temperatures, pressures and other measurement ranges and conditions that can be used to optimize the described process.

### Example 1—Thermoreflectance Enhancement Coatings

Thermoreflectance imaging is a powerful technique to yield high speed thermal imaging of objects. One issue that arises when the surface being imaged is transparent to the probing light source, it is not always possible to know where in the object the reflectance is being generated and thus where the temperature is being measured, e.g., the surface temperature cannot be reliably measured.

By using a coating which enhances the thermoreflectance, it is possible to improve the temperature measurement while also spatially defining the measurement to the device surface. Herein, a coating was utilized to enhance thermoreflectance signals on ultrawide bandgap semiconductors where the signal is generated with light wavelengths below the bandgap of the semiconductor.

Described herein are coatings that provide surface reflectance, which is used to measure the surface temperature of a material or device, leaving the electrical and thermal properties of that material or device unaffected. These coatings are referred to as thermoreflectance enhancement coatings, since they enhance the surface reflection of the light and provide a thermoreflectance signal which can be used to measure the temperature.

Thin films are used which do not significantly impact the operation of the device on which it is applied, while also being reflective to the probe light source and/or having a lower bandgap such that it yields good thermoreflectance. Without loss of generality, layered crystalline materials such transition metal dichalcogenides (e.g., 2D materials like MoS₂) and thermochromic polymers (e.g., poly(ProDOT-alt-EDOT₂) (PE₂)) contain these characteristics for use as thermoreflectance enhancement coatings.

This principle is demonstrated using MoS₂, and poly(ProDOT-alt-EDOT₂) (PE₂) thin films. In this case, both films were deposited using solution processing techniques and are removable via simple bath sonication. However, other deposition techniques such as ink jet printing, spin coating, sputtering, and electron beam deposition are also possible.

Commercial applications can include thermal measurement of wide bandgap semiconductors and materials during operation.

The compositions, methods, and systems described herein allow the measurement of the operational temperature via thermoreflectance imaging of devices containing materials with bandgaps larger in energy than the energy of the probe light.

Demonstration of MoS₂ Thermoreflectance Enhancement Coatings

As a demonstration, molybdenum disulfide (MoS₂) films (<250 nm thick) are used as a thermoreflectance enhancement coating for the thermal imaging of wide and ultrawide bandgap electronic devices during device operation (e.g. field effect transistor). A solution containing MoS₂ in suspension is coated onto the surface of the device (e.g., air jet printing, drop casting, spin coating). After deposition all solvent molecules are removed by evaporation in a vacuum oven (e.g. 200° C. under primary vacuum for 30 min). A light emitting diode (LED) with an energy above the bandgap of MoS₂ and below the band gap of the device material is used to illuminate the MoS₂ coated device. The reflectance (R), which is confirmed to come from the MoS₂ film, is measured with a CCD camera as a function of temperature using a piezoelectric controlled heated stage and the thermoreflectance coefficient (Cₜₕ) is computed:

$$\frac{Δ R}{R} = {C}_{th} Δ T$$

where ΔR/R is the relative change in reflectance observed across the temperature change ΔT. The device is then powered at ambient temperature under pulsed or steady stated conditions, the change in reflectance is measured and the Cₜₕ of the MoS₂ film is used to map the temperature of the device. This enables transient and steady state thermal imaging on the surface of wide and ultrawide bandgap devices using the thermoreflectance of light that is lower in energy than the active materials bandgap.

### Example 2—Thermoreflectance Imaging of (Ultra)Wide Bandgap Devices with MoS₂ Enhancement Coatings

Measuring the maximum operating temperature within the channel of ultrawide bandgap transistors is critically important because the temperature dependence of the device reliability sets operational limits such as maximum operational power. Thermoreflectance imaging (TTI) is an optimal choice to measure the junction temperature due to its sub-micron spatial resolution and sub-microsecond temporal resolution. Since TTI is an imaging technique, data acquisition is orders of magnitude faster than point measurement techniques such as Raman thermometry. Unfortunately, commercially available LED light sources used in thermoreflectance systems are limited to energies less than ˜3.9 eV which is below the handgap of many ultrawide handgap semiconductors (>4.0 eV). Therefore, the semiconductors are transparent to the probing light sources prohibiting the application of TTI. To address this thermal imaging challenge, a MoS₂ coating was utilized as a thermoreflectance enhancement coating which allows for the measurement of the surface temperature of (ultra)wide bandgap materials. This coating is polycrystalline with the c-axis aligned normal to the surface and is easily removable via sonication, The method is validated using electrical and thermal characterization of GaN and AlGaN devices. It is demonstrated that this coating does not significantly influence the electrical and thermal behavior of the devices tested. A maximum temperature rise of 49 K at 0.59 W was measured within the channel of the AlGaN device, which is over double the maximum temperature rise obtained by measuring the thermoreflectance of the gate metal. The importance of accurately measuring peak operational temperature is discussed in the context of accelerated stress testing.

Introduction. The development of wide bandgap (WBG) and ultrawide bandgap (UWBG) electronics has been the focus of much research attention due to their potential to create advanced radio frequency (RF) and power devices. Materials like GaN have played a central role in this development, owing to its large bandgap (E_{g}=3.4 eV), high critical breakdown field (E_{c}), and the formation of a two-dimensional electron gas with high carrier density and mobility. These features enable high voltage and high power devices with fast switching speeds (Amano H. et al. J. Phys. D Appl. Phys. 2018, 51, 163001). Additionally, next generation UWBG systems made from AlGaN and β-Ga₂O₃ are being developed due to their potential for increased performance over lower handgap semiconductors, including GaN. Factors like Johnson Figure of Merit (JFOM=νₛₐₜE_{c}/2π where νₛₐₜ is the saturation velocity and E_{c} is the critical field) are used to compare semiconductor materials for their potential to create high frequency transistors (Johnson E O. Semiconductor Devices: Pioneering Papers, 1991, p. 295-302). The Lateral Figure of Merit (LFOM) is used to compare the theoretically achievable switching performance of lateral transistor architectures (Coltrin M E et al. ECS J. Solid State Sci. Technol. 2017, 6, S3114-S3118). The LFOM can he expressed as qμnₛE_{c}² where q is the charge density, μ is the channel mobility, and nₛ is the sheet charge density. Finally, the Baliga Figure of Merit (BFOM) is used for unipolar vertical devices (Baliga B J. IEEE Electron Device Lett. 1989, 10, 455-457). BFOM is given by εμE_{g}³ where ε is the permittivity of free space and E_{g} is the bandgap. In all cases, these FOMs scale with the critical electric field, E_{c}, which scales nonlinearly with the handgap energy (E_{g}) of the semiconductor (E_{c}∝E_{g}²). Thus, as the bandgap energy increases, large increases in the FOMs arc seen which suggests that WBG and UWBG semiconductors may have a distinct advantage of low bandgap semiconductors like Si for both RF and power switching applications. Another advantage for materials like β-Ga₂O₃ (E_{g}˜4.8 eV) lies in the fact that high crystalline quality substrates can be grown from the melt phase in a manner similar to Si. This is promising since it may yield a pathway to scalable production of low-cost semiconductor substrates for the grow to UWBG β-Ga₂O₃ devices.

One of the challenges that arises from WBG and UWBG devices is that the maximum output power is limited by the high channel temperature induced by localized Joule-heating as a result of the high power densities expected in these devices. The high channel temperatures degrade the device performance and reliability and is thus a major concern (Yates L e. al. IEEE Compd. Semicond. Integr. Circuit Symp. (CSICS) 2016, p. 1-4; Won Y et al. IEEE Trans. Components, Packag. Manuf. Technol. 2015, 5, 737-744). This has led to innovative methods for the thermal management of WBG and UWBG devices which includes the integration of diamond substrates (Cheng Z et al. Appl. Phys. Lett. 2020, 116, 062105; Noh J et al. IEEE J. Electron Devices Soc. 2019. 7, 914-918) and heat spreaders (Yates L et al. IEEE Compd. Semicond. Integr. Circuit Symp. (CSICS) 2016. p. 1-4), high thermal conductivity AlN layers (Pavlidis G et al. IEEE Electron Device Lett. 2019, 40, 1060-1063), flip-chip bonding (Sun J et al. IEEE Electron Device Lett. 2003, 24, 375-377), and double-sided cooling architectures (Montgomery R H et al. J. Appl. Phys. 2021, 129, 085301) to enable high power device performance while limiting the device junction temperature. A critical aspect of these advanced cooling approaches has been the development and utilization of methods that can accurately measure the device temperature to verify its thermal performance. Additionally, accurately measuring the maximum device temperature during operation is critical for predicting reliability and electro-thermal co-design. A simple Arrhenius relationship is commonly used to predict device lifetime (JEP118A. Guidelines for GaAs MMIC PHEMT/MESFET and HBT Reliability Accelerated Life Testing. JEDEC Publication (2018); Cooper M S. IEEE Trans. Components Packag. Technol. 2005, 28, 561-563). Therefore, relatively small errors in the measurement of the maximum device temperature, and in-turn the thermal resistance of a devices can lead to dramatic errors in the estimation of lifetime by accelerated testing methods, particularly when the projecting to different operating conditions (Heller E R. IEEE Trans. Electron Devices 2008, 55, 2554-2560).

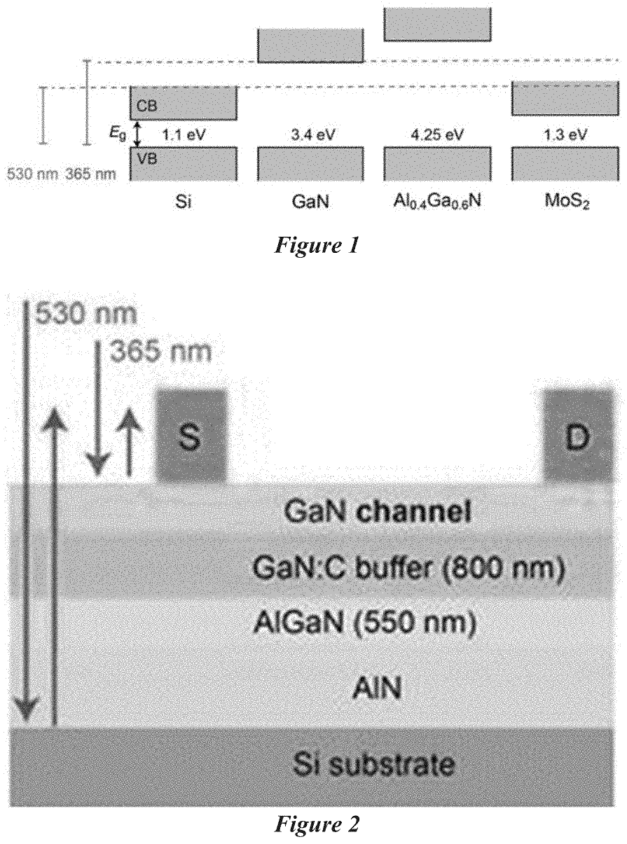

A number of thermal metrology methods have been developed which have been used to measure the junction temperature of lateral and vertical devices made from WBG and UWBG devices. Methods like Raman spectroscopy have been widely used due to its ability to measure the steady state and transient temperature rise in GaN devices with submicron spatial resolution (Maize K et al. 2014 IEEE Compound Semiconductor Integrated Circuit Symposium (CSICS) 2014, p. 1-8). This method typically employs a laser source that is focused through a microscope objective to achieve the high spatial resolution and is thus a single point measurement technique. For materials like GaN, AlGaN, and β-Ga₂O₃, Raman thermography is often performed using sub-bandgap laser energies which means that the semiconductor is transparent to the laser wavelength. Thus, Raman scattering takes place over a significant depth of the semiconductor layer and thus provides an average temperature over the interaction volume. This inherently means Raman provides an average temperature of any thermal gradients that exist in that volume. Methods utilizing Raman active nanoparticles (Lundh J S et al. Appl. Phys. Lett. 2019, 115. 153503) and 2D materials (Lundh J S et al. ACS Appl. Electron. Mater. 2020, 2, 2945-2953) deposited on the surface of semiconductors have also been used which allow for the measurement of surface temperatures by Raman spectroscopy. Gate resistance thermometry has also been applied to lateral devices which allows for the measurement of channel temperatures by monitoring the temperature dependent resistance of the gate metal (Pavlidis G et al. IEEE Trans. Electron Devices 2017, 64, 78-83). Previous research has shown that this method can yield high resolution transient and steady state temperature measurements but confined to the location of the gate. IR thermography provides a full field method to measure the temperature of devices (Sarua A et al. IEEE Trans. Electron Devices 2006, 53, 2438-2447). However, challenges exist in the direct measurement of the device channel of WBG and UWBG devices since they are transparent to IR wavelengths. Thus, when applying IR to the channel regions only qualitative measurements of temperature can be measured using IR thermography since errors can be easily introduced. Another full field method that has been developed is Transient Thermoreflectance Imaging (TTI) which depends on the temperature dependence of reflectivity of light from the surface of the semiconductor devices (Kendig D et al. 2016-22nd Int. Work. Therm. Investig. ICs Syst. (THERMINIC) p. 115-120). This method has been applied to the measurement of the metal contacts in UWBG devices made from AlGaN (Lundh J S et al. Appl. Phys. Lett. 2019, 115, 153503). However, it suffers from the same issues as Raman and IR thermography when applied to the channel region. The readily available light sources are commonly below the bandgap energy and thus the channels are transparent to the light sources used for thermal imaging, particularly for UWBG materials (FIG. 1). In limited cases, direct measurements of the channel temperature using UV light sources (e.g., 365 nm) have been accomplished with GaN devices (Pavlidis G et al. IEEE Trans. Electron Devices 2020, 67, 822-827). Limitations in available light sources prohibits the application this method to UWBG devices since the bandgap energies for these materials are typically far above the light source energy. While TTI has shown promising capabilities in terms of spatial (submicron) and temporal (10 ns) resolution, challenges exist in applying this technology to the channel of WBG and UWBG devices due to the transparency of the semiconductors to the light sources.

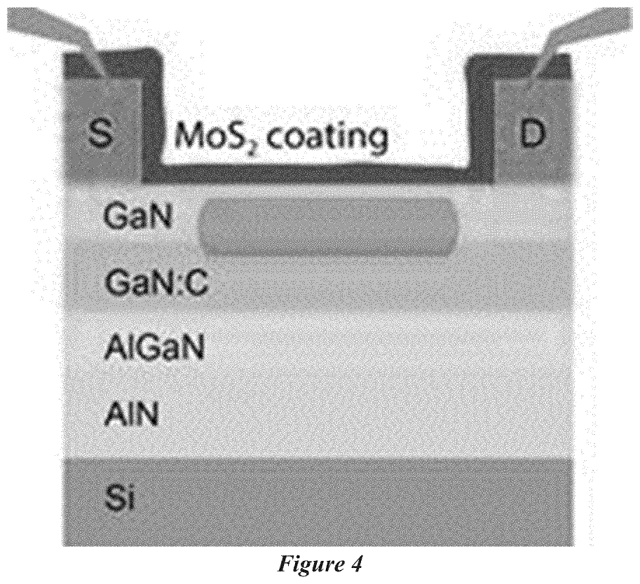

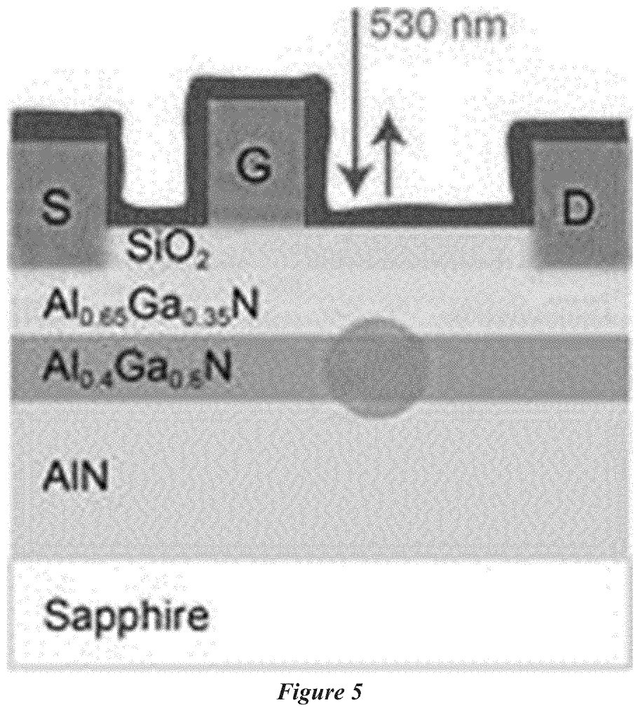

Herein, a method is presented to overcome the challenges of applying TTI to WBG and UWBG device channels by deploying a low bandgap layered material to the surface of the devices. Herein, MoS₂ coatings are used which enhance the thermoreflectance from the surface of the WBG and UWBG materials while not impacting the electrical performance of the devices (FIG. 2-FIG. 5). The surface coating provides the ability to measure the full field temperature of operational devices using TTI. The coating, which is removable, provides the flexibility needed to extend the TTI technique to the rapidly emerging class of (U)WBG power electronics, independent of bandgap energy.

### Methods

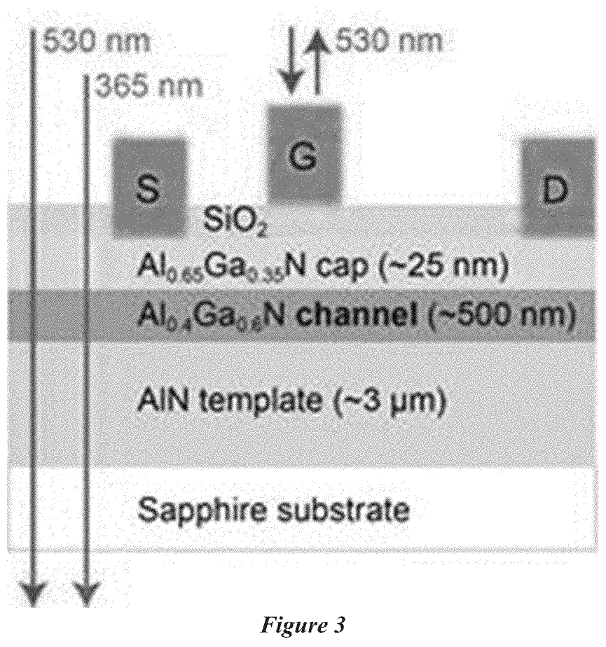

Devices. Two types of devices were used to validate the MoS₂ thermoreflectance coating: (i) a GaN on Si transition line method device (TLM, FIG. 2) and (ii) an AlGaN metal oxide semiconductor heterostructure field effect transistor (MOSHFET, FIG. 3) (Mollah S et al. Appl. Phys. Lett. 2020, 117, 232105). The channel temperature of the GaN device can be measured before applying the MoS₂ coating using near-band gap TTI with a wavelength of λ=365 nm (Pavlidis G et al. IEEE Trans. Electron Devices 2020, 67, 822-827). Therefore, this device is optimal for verifying the MoS₂ TTI enhancement coating method. As an added benefit of the technique, it was found that measuring the GaN device using the MoS₂ and λ=530 nm light can avoid unwanted opto-electronic effects (induced by excitation of carriers across the bandgap) which are not native to standard device operation, as well as improve the temporal resolution during transient characterization. The channel temperature of the AlGaN device cannot be measured using thermoreflectance without the MoS₂ coating, which further demonstrates the methods utility. The AlGaN gate metal temperature before and after coating can be used as another benchmark for method validation. The GaN device measured in this study is on the same wafer as the device labeled AL3 in the work by Pavlidis et al. (Pavlidis G et al. IEEE Trans. Electron Devices 2020, 67, 822-827). In this work a two-terminal TLM device with a channel length of 20 μm was used to validate the MoS₂ TTI enhancement coating approach. The AlGaN device fabrication started with mesa-isolation using Cl₂-based Inductively Coupled Plasma Reactive Ion Etching (ICP-RIE). The source and drain ohmic contact metal stack Zr/Al/Mo/Au (15/100/40/30 nm) were deposited using an E-beam evaporation system and subsequent annealing was performed at 950° C. under N₂ environment. 10 nm SiO₂ was deposited as gate insulator using Plasma Enhanced Chemical Vapor Deposition (PECVD) followed by the Ni/Au (100/200 nm) gate metallization using E-beam. The fabrication process is described in more detail by Mollah et al. (Mollah S et al. Appl. Phys. Lett. 2020, 117, 232105; Mollah S et al. Appl. Phys. Express 2021, 14, 0-4).

MoS₂ Coating Procedure and Film Characterization.

Gravity drop coating. MoS₂ in a suspension containing IPA and acetone was obtained from CRC Industries (Product No. 03084). The as received suspension was sonicated for 90 min and filtered to remove agglomerations. Just before film deposition, the suspension was sonicated again for 5 minutes. MoS₂ films were deposited by supporting the device wafer at a ˜45° angle, oriented such that a drop will roll across the channel, perpendicular to the direction of charge transport. This avoids agglomeration of flakes at the edge of the electrodes. A micropipette was used to deposit a drop on the wafer which then rolls over the device to be measured, not allowing the MoS₂ suspension to pool on top of the device. The orientation of this gravity drop coating procedure can be important for achieving uniform high reflectivity. The film was then annealed in a vacuum oven at 200° C., under roughing vacuum (˜10² torr) to remove any remaining solvent molecules. An MoS₂ film was cast onto a 100 Si wafer (SiO₂ surface) using the same gravity drop coating and annealing technique. This test film was used to characterize the particle size, orientation, film thickness, uniformity, and chemical analysis.

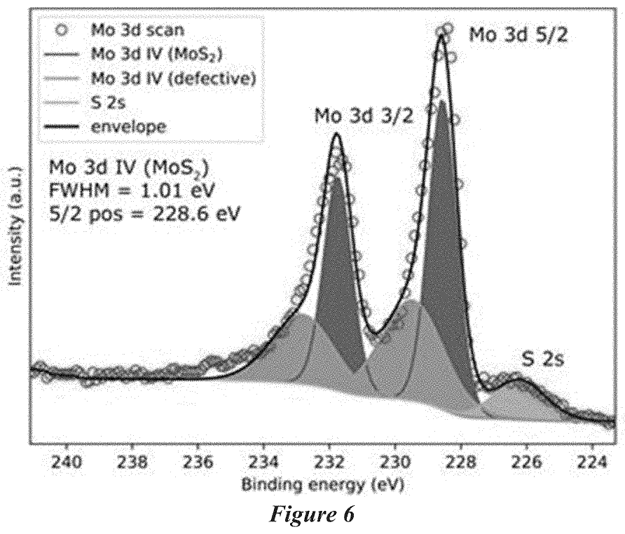

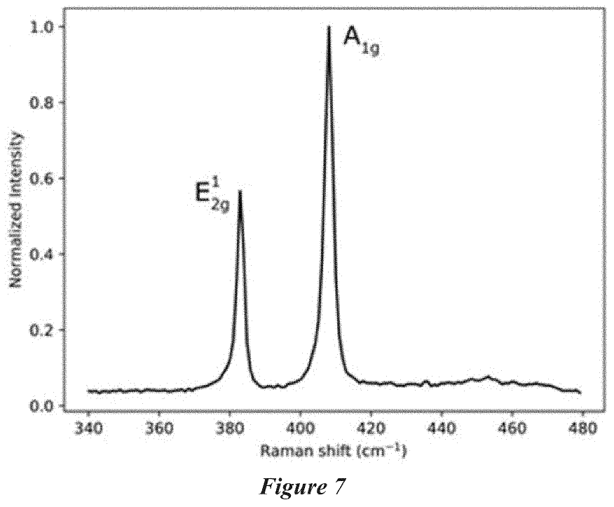

X-ray photoelectron spectroscopy (XPS). XPS was used to characterize the deposited MoS₂ films FIG. 6. High resolution scans (0.1 eV step size) covering the Mo 3d doublet peak (3/2 and 5/2) and S 2s peak was collected using Al Kα radiation and a 500 μm spot size on a Thermo Scientific ESCALAB 250Xi. The procedure for decomposing the Mo 3d peaks presented by Baker et al. was applied using ThermoAdvantage peak fitting software (Baker M et al. Appl. Surf. Sci. 1999, 150, 255-262). A measure of the primary Mo 3d double peak FWHM provides a metric for defects and disorder in the MoS₂ film (Baker M et al. Appl. Surf. Sci. 1999, 150, 255-262). Additionally, an increased intensity of the secondary Mo 3d doublet peak at higher binding energy can indicate the level of oxide present. Since XPS only probes near the surface of the film, 30 s of ion etching was used to remove adventitious carbon on the surface (which masks the Mo signal) and increase the signal to noise ratio when needed.

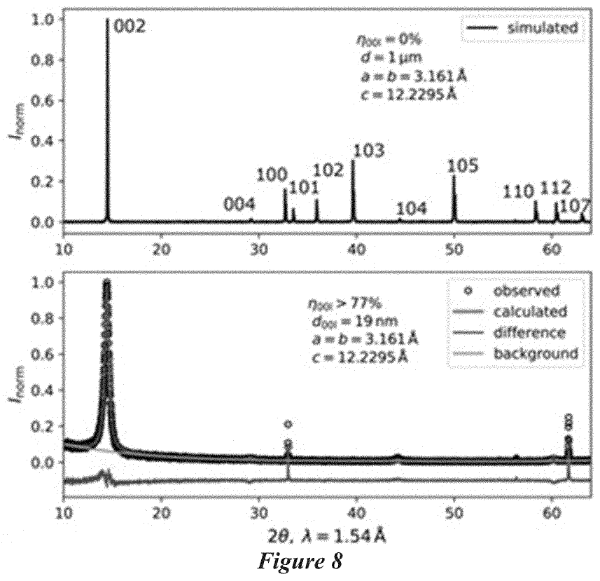

Particle size and orientation. The MoS₂ film on Si was also used to obtain a characteristic size and particle orientation via X-ray diffraction (XRD). XRD in Bragg-Brentano geometry along with refinements (using GSAS-II (Toby B H et al. J. Appl. Crystallogr. 2013, 46, 544-549)) were used to characterize the size and orientation of the MoS₂ particles in the coating (FIG. 8) (Holder CF et al. ACS Nano 2019, 13, 7359-7365; Zolotoyabko E. J Appl. Crystallogr. 2009, 42, 513-518), The March-Dollase ratio with 001 as the unique axis was used to characterize the percent orientation, η₀₀₁ (Zolotoyabko E. J. Appl. Crystallogr. 2009, 42, 513-518). The top panel of FIG. 8 is a simulated pattern for randomly orientated MoS₂ particles with an isotropic size of 1 μm, for comparison with the measured data. With the given counting statistics, the maximum observable orientation was η₀₀₁=77%, and this is shown in the refined model given as red line in the bottom panel of FIG. 8. However, since equivalent fits were obtained by setting η₀₀₁=100%, it was concluded that the orientation of the MoS₂ coating is larger than 77%. From the broadening of the [002] peak, the refinement obtained a c-axis particle size of 19 nm, which is ˜10 conventional unit cells or ˜20 MoS₂ layers thick. Since there were not enough peaks observed to refine the full unit cell, the lattice parameters were fixed to a=b=3.161 Å and c=12.2295 Å. Therefore, the only refined parameters were d₀₀₁ and η₀₀₁ resulting in a reduced X² of 3.2. There are two sharp unidentified peaks at 2θ=33.0° and 61.7°, which may indicate a small number of 100 orientated particles.

Raman. Raman spectroscopy was used for film characterization on a Renishaw InVia Micro-Raman system. The Ar+ laser wavelength is 488 nm. The objective is a Leica 0.50 NA 50× with 1.19 μm theoretical diffraction-limited spot size. The acquisition time is 30 s with 5 accumulations. Since the film contained highly aligned particles and only the [002] XRD peak was observed, the presence of the characteristic MoS₂ E_{2g}¹ and A_{1g} peaks provide additional chemical verification through optical phonon properties.

Thickness and uniformity. After deposition and annealing the thickness and uniformity were characterized. The thicknesses of the films were then measured using a Bruker DektakXT stylus profilometer, and the region of interest was checked for pooling an agglomeration of MoS₂. A small scratch was made in the film with a needle probe and the step height from substrate to film was used to measure the thickness. The film thickness on the devices under testing which was between 200 nm to 350 nm.

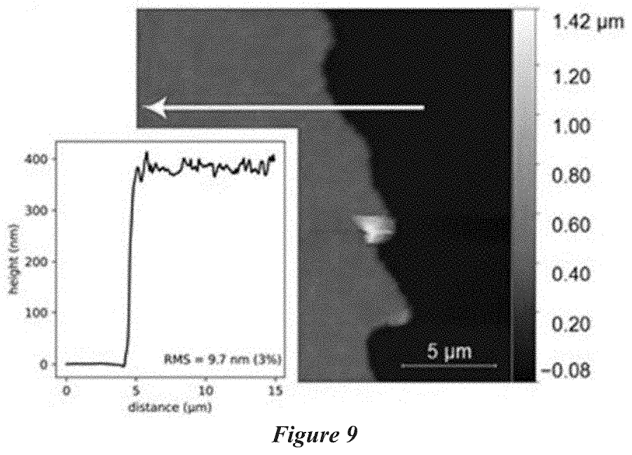

Atomic force microscopy (AFM) was used to measure film uniformity (FIG. 9). The MoS₂ test film was used to obtain a characteristic root-mean-squared (RMS) film roughness which is reported in FIG. 9. The drop coated test film was measured to have a low RMS roughness value of 9.7 nm.

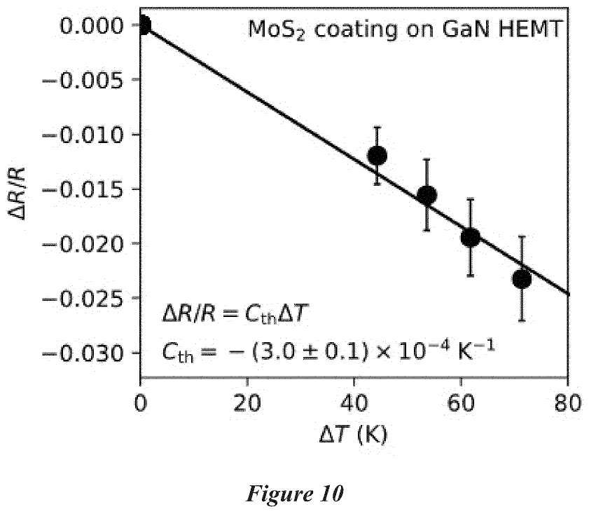

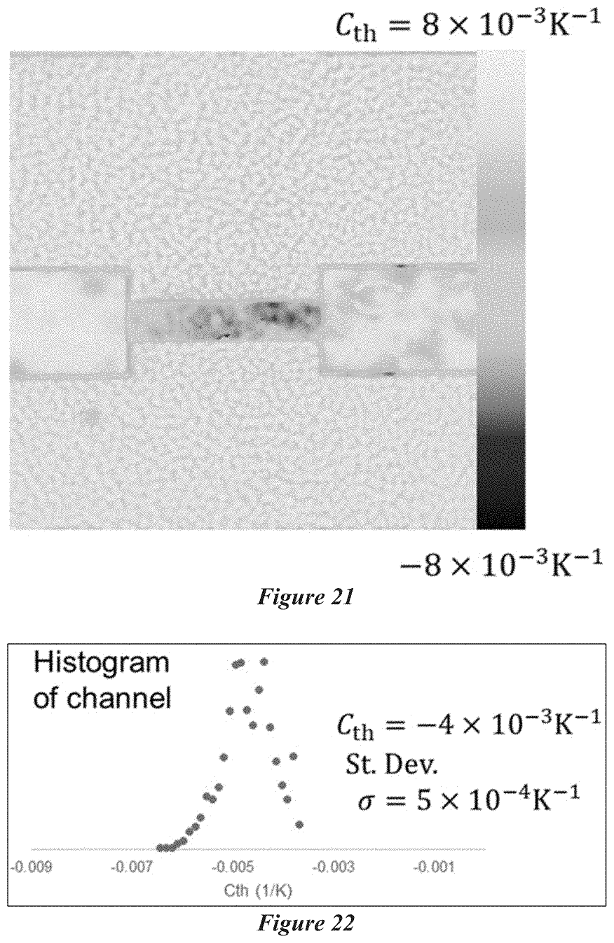

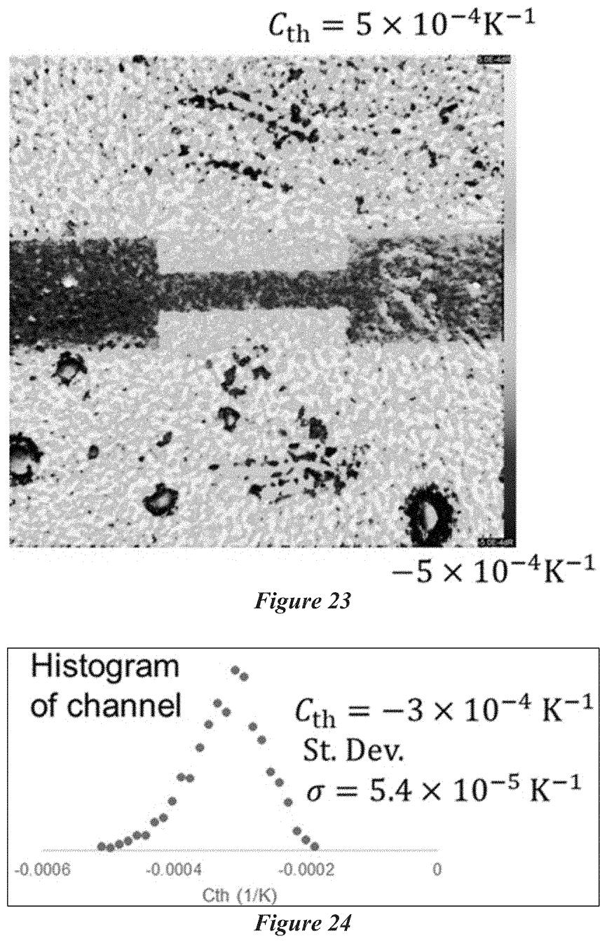

Thermoreflectance thermal imaging (TTI). A Microsanj NT220B was used for the coefficient of thermoreflectance (Cₜₕ) calibration and measurement of temperature rise (ΔT). Values for Cₜₕ were measured by averaging the relative change in reflectivity (ΔR/R) across at least five hot-cold temperature cycles with a magnitude of ΔT, where ΔRR=CₜₕΔT. The Cₜₕ of the MoS₂ film which was deposited on the GaN device is shown in FIG. 10. Each point given in the ΔR/R vs. ΔT plot is determined by six hot-cold temperature cycles. The error bars represent the standard deviation of the ΔR/R measurements over a region of interest of approximately 20 μm by 5 μm in the center of the TLM channel. These error bars are a measure of the uniformity of the thermoreflectance coefficient across the film. However, since pixel-by-pixel calibration can be performed (FIG. 21-FIG. 24), which does not require Cₜₕ to be uniform across the image, these error bars do not correspond to the resulting temperature measurement error. Rather they are a metric of uniformity of the optical properties of the film. A key metric for determining the temperature measurement error is the range of variation in Cₜₕ between measurements which was determined to be (−3.0±0.1)×10⁻⁴ K⁻¹ (reported FIG. 10).

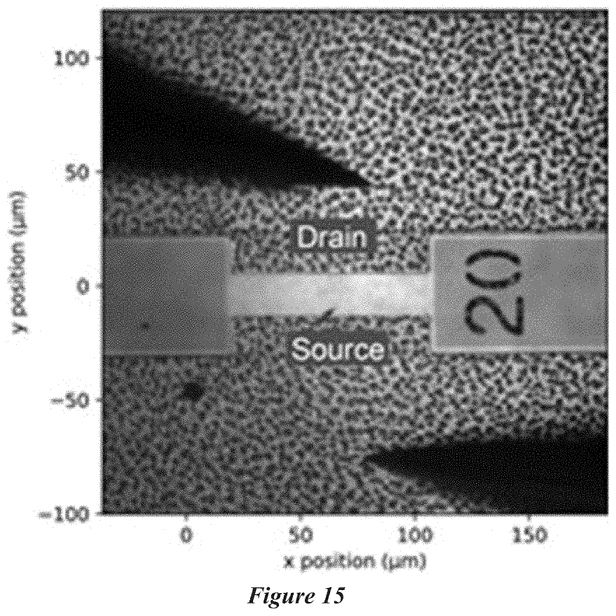

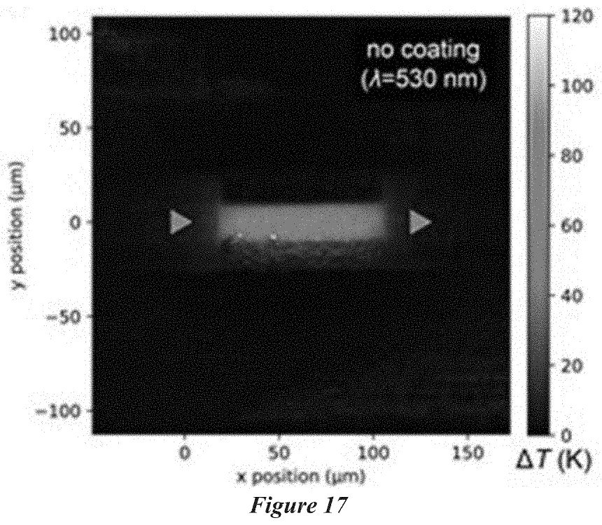

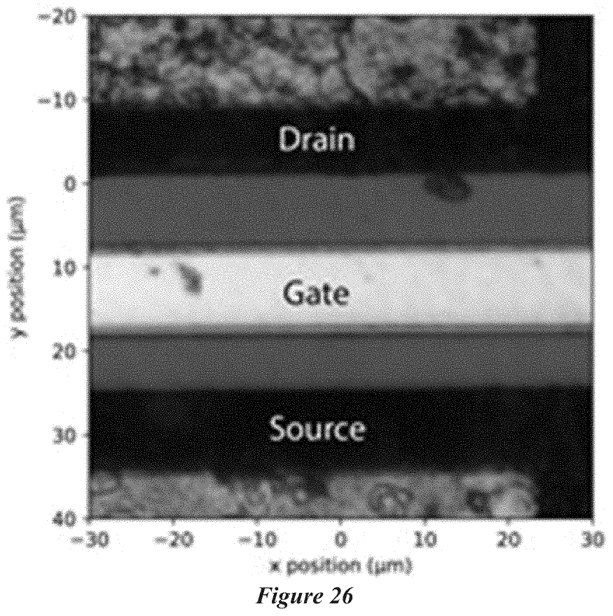

A 50× Leica objective lens was used which results in an image resolution of 0.108 μm per pixel. This lens exhibits low UV absorption such that it can be used with both the 530 and 365 nm LED. A 365 nm band pass filter was used to reduce the bandwidth of the 365 nm LED and increase the signal to noise ratio (Pavlidis G et al. IEEE Transactions on Electron Devices 2020, 67(3), 822-827). Image filtering was performed in sanjANALYZER. Pixels were binned into 4×4 blocks and a 5×5 median filter (which assigns the median value of a moving 5×5 pixel box to the central pixel) was used. By analyzing the data with and without image filtering, it was confirmed that the image filtering does not influence the measured temperature but decreases the measurement standard deviation. Therefore, spatial resolution is sacrificed to reduce the standard deviation of the temperature rise, without affecting the resulting temperature measurements. The resolution of the measurement after image filtering was 0.432 μm. Both the CCD and ΔT images in FIG. 15-FIG. 20 and FIG. 26-FIG. 30 are shown after image filtering. A single Cₜₕ=−3×10⁻⁴ K⁻¹ coefficient was used to obtain the thermal images in FIG. 15-FIG. 20 and a pixel-by-pixel Cₜₕ map was used in FIG. 26-FIG. 30.

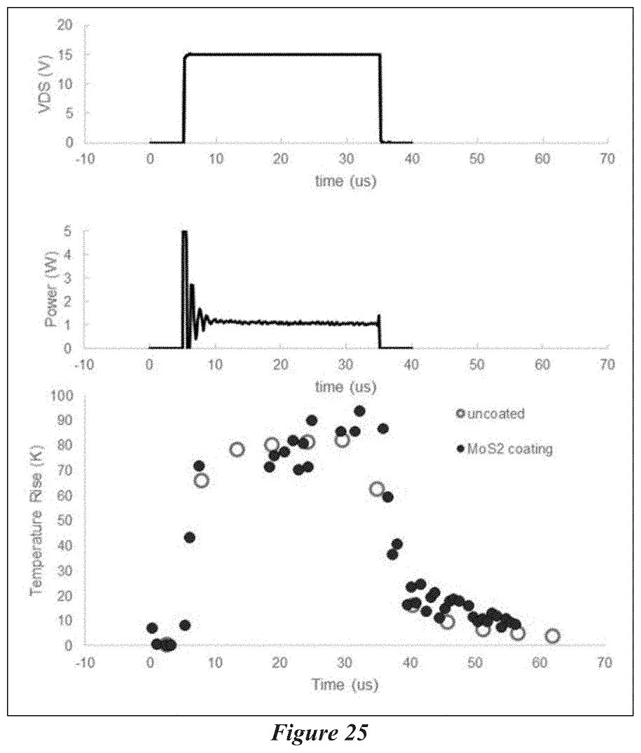

Both GaN and AlGaN devices were measured under pulsed conditions using a 30% duty cycle and a 100 μs period. The AlGaN MOSHFET drain-source voltage was V_{DS}=20 V in the on state and V_{DS}=0 V in the off state. The gate-source voltage was V_{GS}=0 V in the on state and V_{GS}=−12 V in the off state. The GaN device had a V_{DS}=15 V on state, a V_{DS}=0 V off state and was a TLM structure so therefore had no gate. The power driven through the AlGaN device in the on state was 0.59 W. The power driven through the GaN TLM device in the on state was 0.86 W. All thermal images were taken at 15 μs into the 30 μs pulse, which was determined to be pseudo steady state conditions. An example of transient pulse data is shown in FIG. 25 for the GaN device with and without the MoS₂ coating.

Results

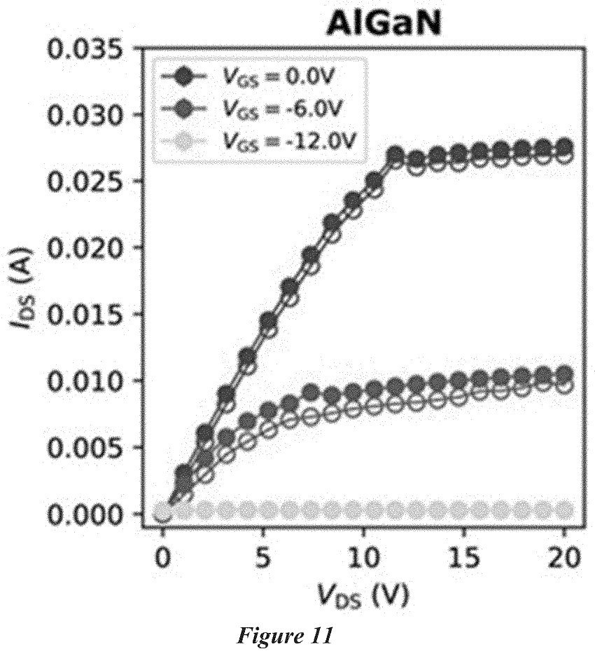

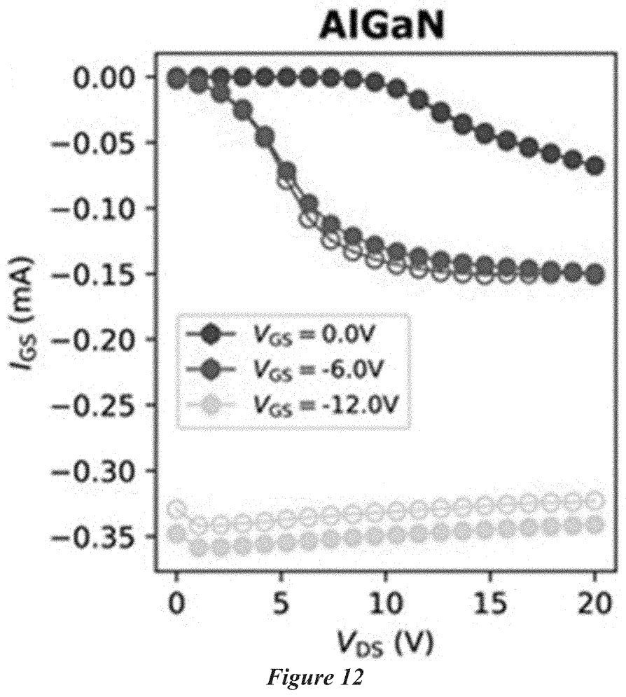

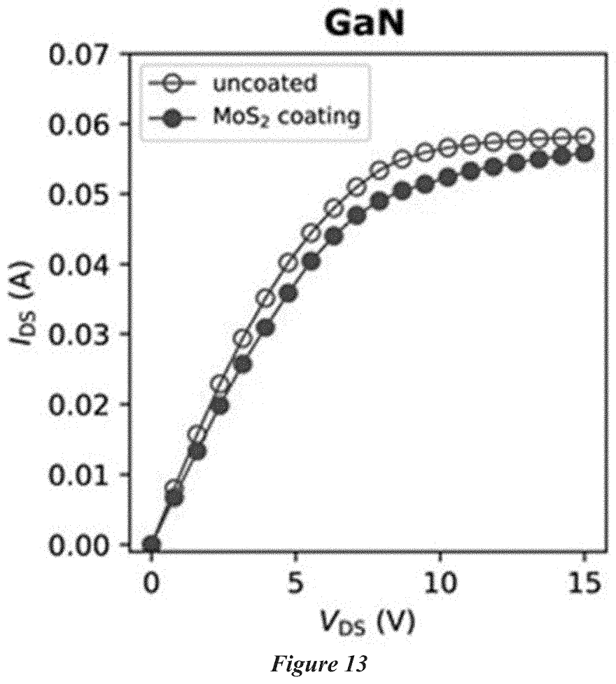

Electrical properties. The electrical properties of the devices were characterized before and after application of the MoS₂ film, to ensure the coating does not influence the electrical behavior of the device. FIG. 11-FIG. 14 shows the IV characteristics of the AlGaN transistor and GaN TLM device before (open circles) and after (filled circles) coating and annealing. It was important to ensure the needle probes achieved contact with the metal pads by scratching through the MoS₂ film, and the reported IV characteristics were unchanged after remaking electrical contact. The results indicate that the electrical performance of the devices is negligibly affected (no more than 5%). This level of current variation is commonly observed due to natural aging of the device and may not be associated with the MoS₂ film.

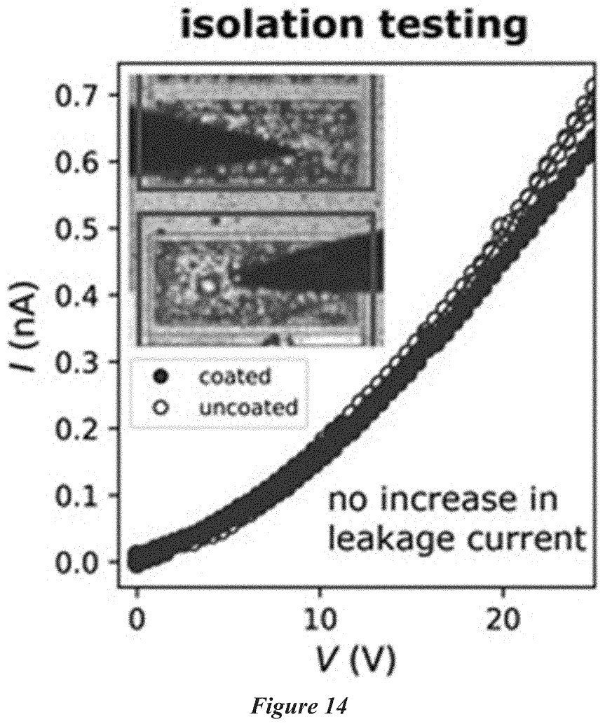

While the I_{DS} and I_{GS} values for the AlGaN device were unchanged, there is motivation for a stricter test to detect any current leakage that may occur through the MoS₂ film. FIG. 14 shows the current measured through two electrically isolated contact pads (denoted by the red lines in the inset). Any current measured in this test must pass through the highly resistive substrate or the MoS₂ film. As can be seen the introduction the MoS₂ film does not measurably increase leakage current (in the nA range).

Thermal Imaging

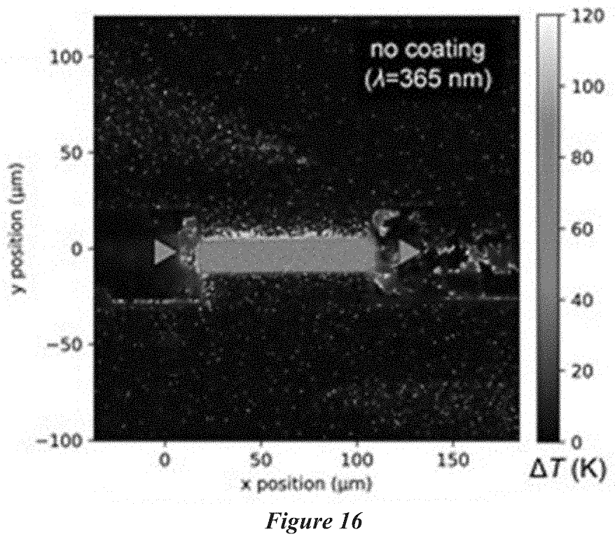

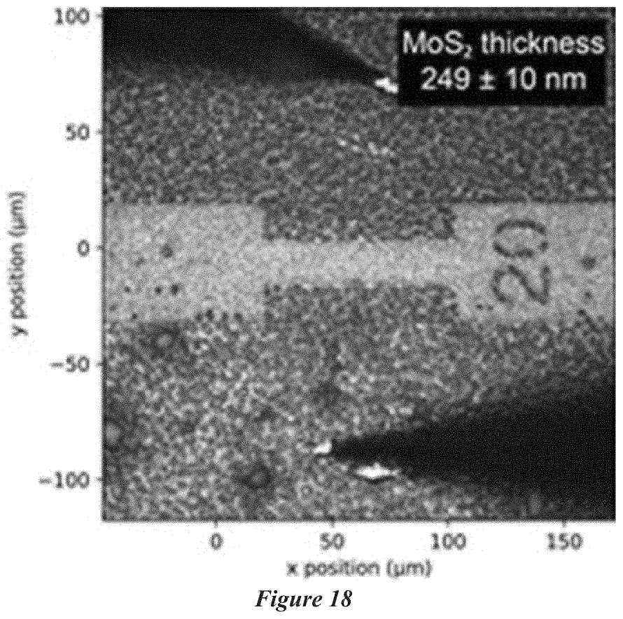

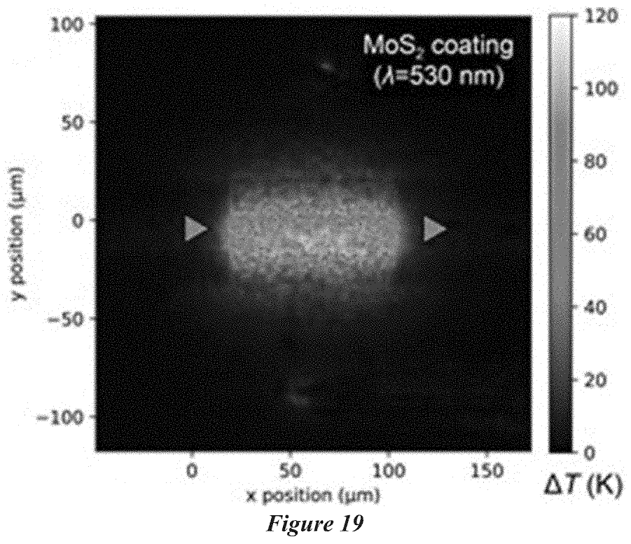

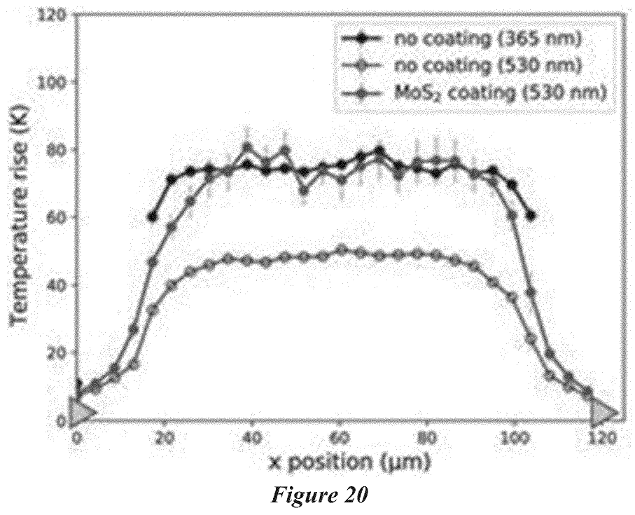

GaN TLM. The thermal imaging of the GaN TLM device is shown in FIG. 15-FIG. 20. Recall that a 365 LED reflects off the surface of the GaN channel, whereas a 530 nm LED is transparent to the channel surface and is expected to reflect primarily off of the Si wafer underneath. CCD images before and after coating with MoS₂ are given in FIG. 15 and FIG. 18. Since GaN has a band gap near 365 nm, the channel temperature can be measured using near band gap TTI following the procedure provided by Pavlidis et al. (Pavlidis G et al. IEEE Trans. Electron Devices 2020, 67, 822-827). Therefore, at the same pulse power conditions, a comparison of ΔT between uncoated 365 nm (FIG. 16, filled blue data points in FIG. 20) and MoS₂ coated 530 nm TTI (FIG. 19, filled green data points) provides a simple validation test of this technique. 1D ΔT slices through the center of the channel agree between the two cases as shown in FIG. 20. Each data point corresponds to the average ΔT of a box with dimensions (Δx, Δy)=(4.32 μm, 4.32 μm). The error bars indicate a 98% confidence interval of the ΔT data within the box. Any data point where the 98% confidence interval is greater than 40% of the mean is omitted.

Now TTI using a 530 nm before and after the MoS₂ coating is applied was compared. When using a 530 nm LED, the Max ΔT obtained without the coating is nearly half that obtained when the MoS₂ coating is used. As can be seen in the device layer structure provided in FIG. 2, a 530 nm is expected to reflect off of the buried Si wafer, which is expected to be colder than the surface of the GaN channel. Additionally, the thermoreflectance coefficient from the 530 nm LED in the channel without the coating is Cₜₕ=+1.17×10⁻⁴ K⁻¹. The 530 nm Cₜₕ measured in the channel after MoS₂ coating is −3×10⁻⁴ K⁻¹ (FIG. 10). Therefore, the measured Cₜₕ of the 530 nm LED changes sign after the MoS₂ is deposited. Both of these results provide confidence that the thermoreflectance signal is indeed dominated by the thermoreflectance enhancement coating.

AlGaN MOSHFET. All layers of AlGaN device structure are transparent to both 530 nm and 365 nm LEDs. The only location where a thermoreflectance signal can be obtained without the MoS₂ coating is on top of the gate metal (FIG. 26). For fixed device operating conditions, the ΔT measured on the gate metal before and after coating can be used as another benchmark to validate the method. Most importantly, the MoS₂ TTI enhancement coating enables the measurement of the temperature within the channel, where the light would be otherwise transparent to the device.

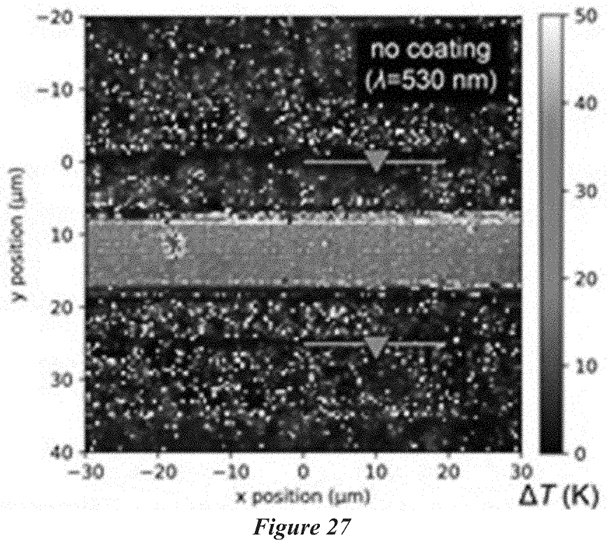

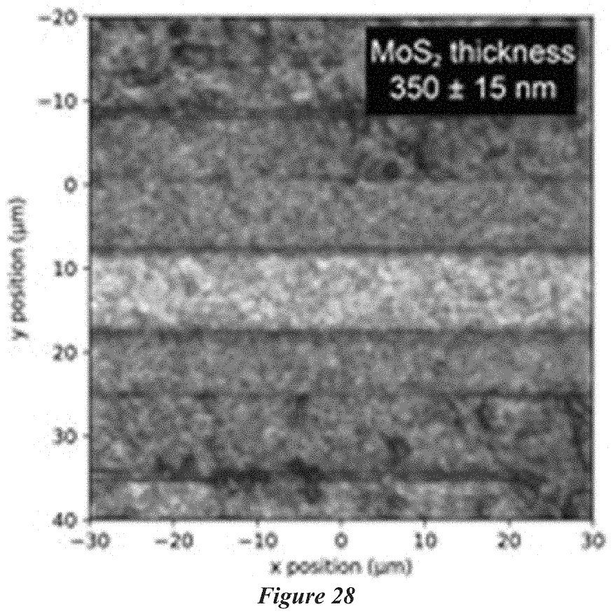

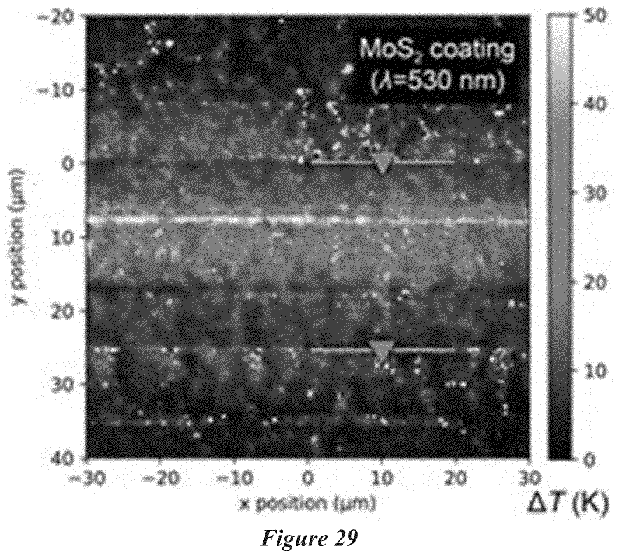

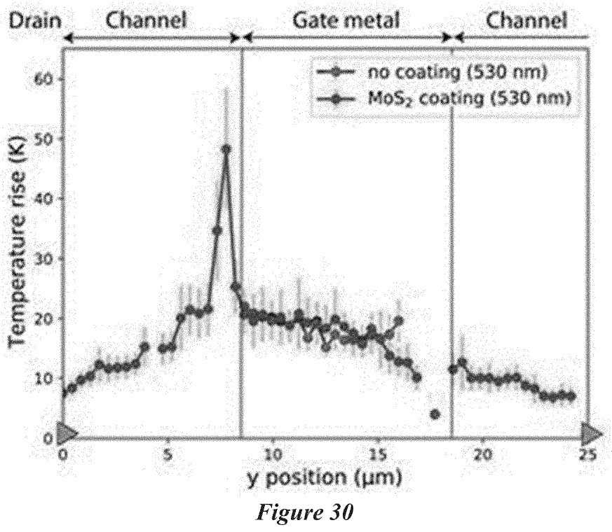

FIG. 26 and FIG. 28 show the CCD image before and after the MoS₂ coating procedure, respectively. The thermal images before and after MoS₂ coating are shown in FIG. 27 and FIG. 29. The corresponding 1D ΔT slices are shown in FIG. 30. The data points indicate the average over a box with dimensions (Δx, Δy)=(21.6 μm, 0.432 μm). The error bars again indicate a 98% confidence interval. Any data point with a 98% confidence interval greater than 40% of the mean is omitted and is considered noise. At the top of FIG. 30, the position of the drain, channel, and gate metal are indicated. It can be seen that for the uncoated case, data in the channel between the gate and drain is automatically omitted. Therefore, it is concluded that the ΔT data within the channel in FIG. 27 is simply noise. In contrast, the MoS₂ enables the reliable thermal imaging of the AlGaN channel surface temperature. A maximum ΔT of 50 K located within the channel near the drain side of the gate is measured. It is well known that when a transistor in its open state (which is the case here) the maximum electric field is near the drain side edge of the gate metal; the hot spot was measured in that same location.

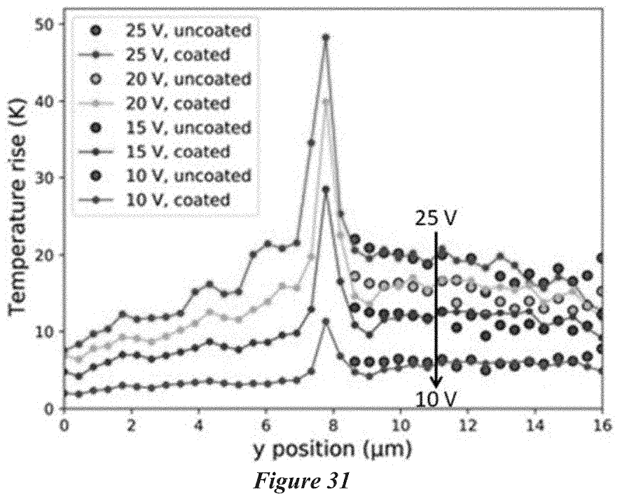

The AlGaN device was powered at various V_{DS} conditions, keeping the pulse conditions and V_{GS} constant. FIG. 31 shows the same temperature profile as indicated in FIG. 29 under different power conditions. The larger unconnected data points show the uncoated gate metal temperature rise. This data agrees with the MoS₂ coated temperature rise at every power condition measured, shown as smaller connected data points.

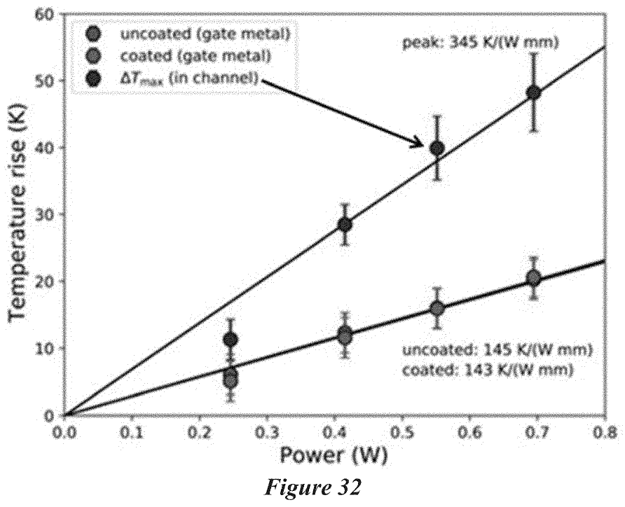

From this data two device thermal resistances can he obtained: (i) from data without the use an MoS₂ coating using the maximum gate metal temperature and (ii) from data with an MoS₂ coating using the maximum device temperature which occurs within channel. These two thermal resistances are given in FIG. 32, and it can be seen that the thermal resistance obtained using the MoS₂ coating is over double the thermal resistance obtained without said coating. This discrepancy can have a profound impact on the electro-thermal co-design of UWBG transistors as well as accelerated testing.

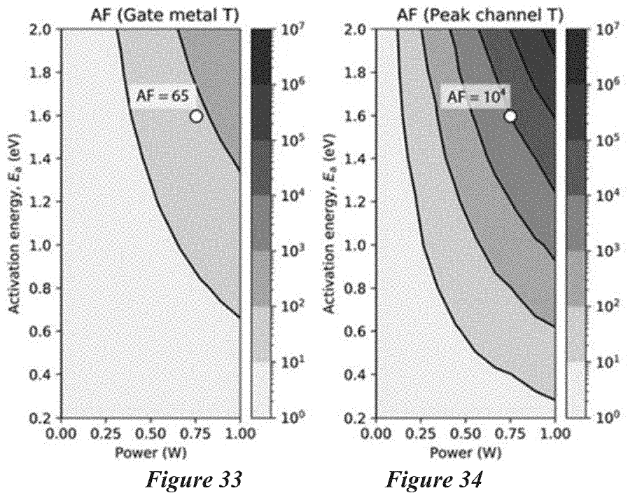

Implications for reliability testing. When developing a new RF or power electronic device, accelerated testing can he an essential tool to estimate device reliability (Heller E R. IEEE Trans. Electron Devices 2008, 55, 2554-2560). Standards have been established for established technologies based on Si (JEP122H. Failure Mechanisms and Models for Semiconductor Devices. JEDEC Publication (2016)) and GaAs (JEP118A. Guidelines for GaAs MMIC PHEMT/MESFET and HBT Reliability Accelerated Life Testing. JEDEC Publication (2018)). As knowledge matures it can be possible to write a generalized relationships that may contain variables pertinent to the physics of failure such as temperature, current, and electrical field (JEP122H. Failure Mechanisms and Models for Semiconductor Devices. JEDEC Publication (2016)). For less mature devices, however, it is common to first model time to failure (t) using an Arrhenius relationship (Cooper M S. IEEE Trans. Components Packag. Technol. 2005, 28, 561-563):

$$t ( T ) = t ( {T}_{0} ) exp [ \frac{{E}_{A}}{{k}_{B} {T}_{0}} ( \frac{{T}_{0}}{T} - 1 ) ] \qquad Eq . 1$$

where k_{B} is the Boltzmann constant, and T₀ is the reference temperature (taken to be ambient temperature in FIG. 33-FIG. 34), on the expectation this is a dominant term. Errors from missing physics are minimized by, for example, carefully considering voltage, current, etc. of interest when doing the accelerated testing and looking for unexpected effects. Certain device failure mechanisms (e.g. metallic diffusion, intermetillic growth, and time-dependent dielectric breakdown) have an associated activation energy E_{A} (typically spanning from 0.2 eV to 2 eV (Shover M. Accelerated Life Test Principles and Applications in Power Solutions. Advanced Energy Industries Inc. 2018, p. 1-8)) and can be greatly accelerated by increased temperature. Within this framework T is the temperature at the failure point which is often at the hot spot during operation. Heller identified that when projecting an accelerated reliability test to power conditions not explicitly tested, significant errors in the predicted time to failure can arise, if the accurate temperature at failure is not characterized (Heller E R. IEEE Trans. Electron Devices 2008, 55, 2554-2560).

The acceleration factor is given by:

$$AF = \frac{t ( T )}{t ( {T}_{0} )} = exp [ \frac{{E}_{A}}{{k}_{B} {T}_{0}} ( \frac{{T}_{0}}{T} - 1 ) ] \qquad Eq . 2$$

and is shown in FIG. 33-FIG. 34 for various failure mechanism E_{A} values under varying power conditions. This simple analysis demonstrates the importance of accurately measuring the peak temperature. FIG. 33 utilizes a thermal resistance of 145 K/(W mm) to convert the operating power to device temperature and FIG. 34 utilizes 345 K/(W mm). In this example, for reasonable choices of T, power, E_{A}, etc., a thermal resistance which is under-estimated by a factor of 0.42 under predicts time to failure by over two orders of magnitude.

Conclusion. Thermoreflectance imaging is a promising tool enabling electro-thermal co-design which can accelerate the development of radio frequency and power electronics. However, its application to WBG and UWBG devices can be limited since the transistor channel is often transparent to available light sources. A coating was developed herein which enhances the surface reflection from the device without measurably impacting the devices electrical or thermal properties, enabling the measurement of device operating temperature. This technology broadens the applicability of thermoreflectance imaging to the rapidly emerging industry of UWBG transistors.

### Example 3—A Demonstration of a Thermochromic Polymer Thermoreflectance Enhancement Coatings

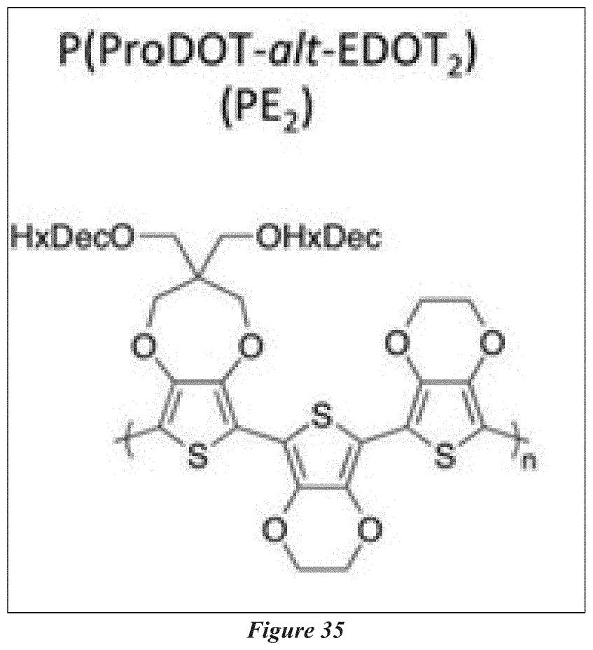

Overview. Thermochromic polymers are a class of materials that could be used for thermoreflectance enhancement coatings. Polymer films commonly exhibit low thermal and electrical conductivity (when left undoped), such that they are expected to minimally effect the electrical and thermal properties of a material or device it is deposited on. However, the polymer must have a thermochromic effect, such that the reflectance changes with temperature and provides sufficient thermoreflectance signal. The thermoreflectance coefficient (Cₜₕ) properties of a P(ProDOT-ald-EDOT₂) (PE₂, FIG. 35) thin film deposited on glass microscope slide are presented herein. Cₜₕ can be computed from the relative change in reflectivity (ΔR/R) and the change in temperature (ΔT) as:

$$\frac{Δ R}{R} = {C}_{t h} Δ T .$$

The data presented here shows that thermochromic polymers, such as PE₂, could be used as a thermoreflectance enhancement coating.

Methods

Material synthesis and deposition. The synthesis and deposition process of the PE₂ films is detailed by Ponder et al. (Ponder J F et al. Adv. Energy Mater. 2019, 9, 1-7). The film measured here is approximately 0.5 μm thick and was blade coated on a transparent glass slide.

Thermoreflectance. A Microsanj NT220B was used for measurement of Cₜₕ. Values for Cₜₕ were measured by averaging the ΔR/R values of three hot-cold temperature cycles with a magnitude of ΔT. Thermal paste was used to thermally connect the glass slide to the heated stage. A scratch was made on the film exposing the transparent glass slide, thermal paste, and copper hot plate underneath. A 530 nm LED was used.

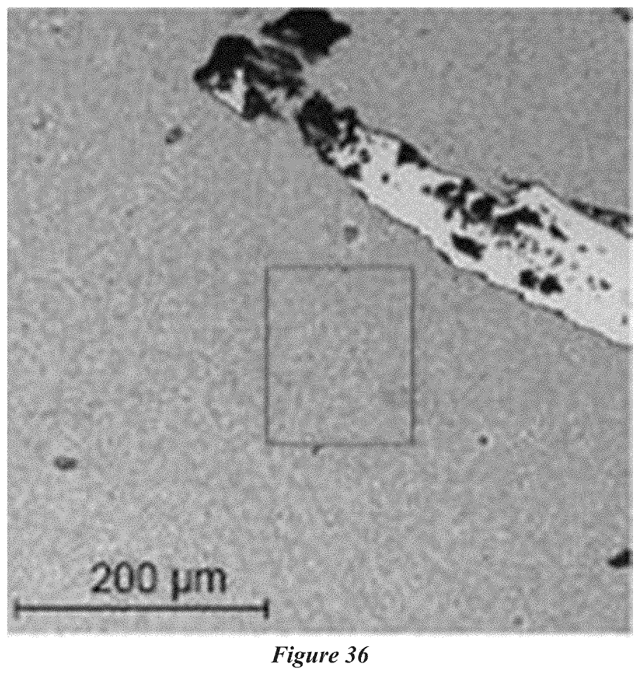

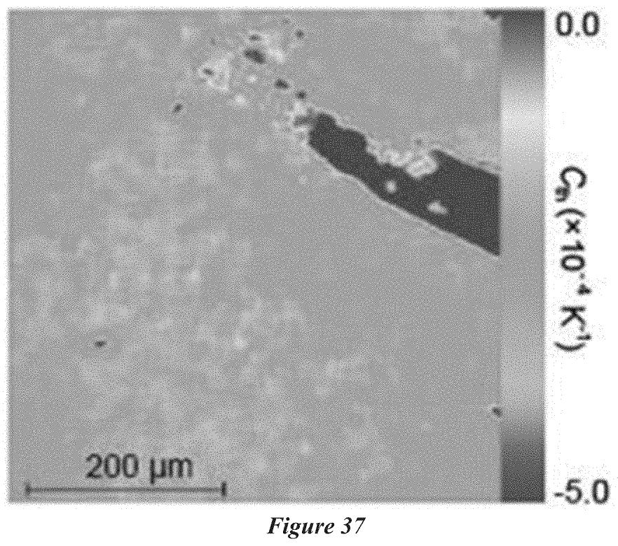

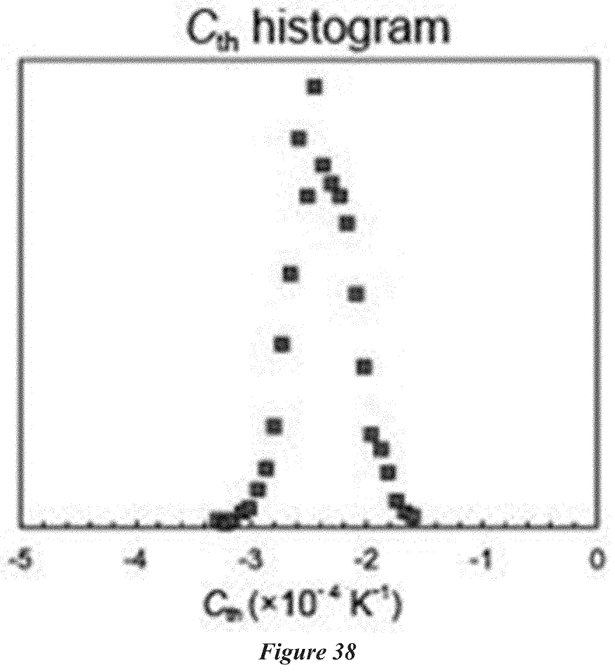

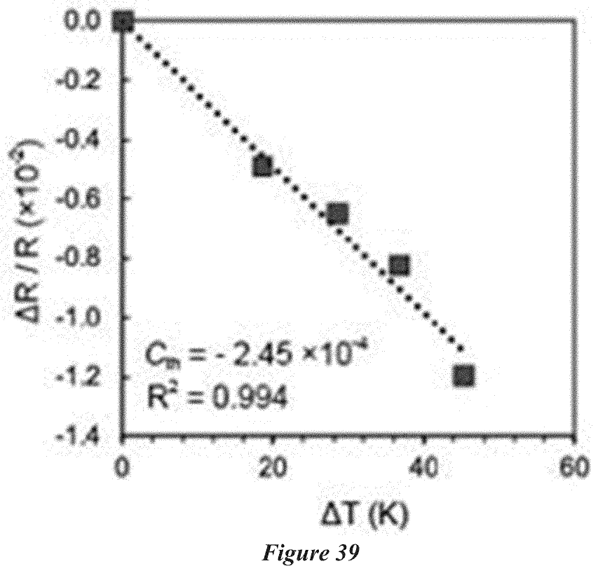

Results. The CCD image of the film and scratch are shown in FIG. 36. It can be seen in FIG. 37-FIG. 39 that the Cₜₕ of the film is −2.45×10⁻⁴ K⁻¹. In the region of the scratch, which exposes the transparent glass slide and thermal paste underneath, Cₜₕ is close to zero (FIG. 37). This confirms that the light from the 530 nm LED indeed reflects off of the PE₂ film, and that the Cₜₕ obtained is sufficiently large for thermal imaging.

### Example 4—TTI: MoS₂ Coating on GaN HEMTs

Plan-Perform 1) IV measurements, 2) Cₜₕ measurements, and 3) pulse thermal measurements on GaN device that is i) uncoated, ii) coated with molylube, and iii) coated with MoS₂.

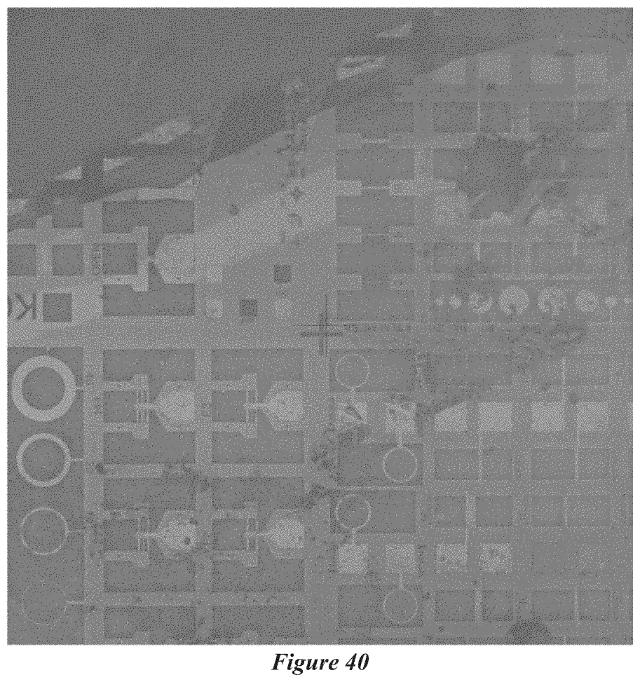

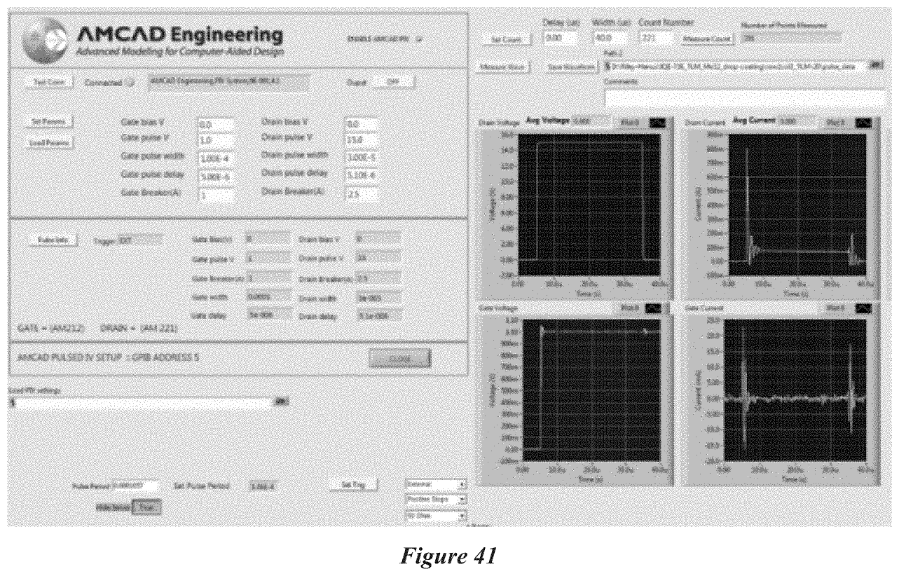

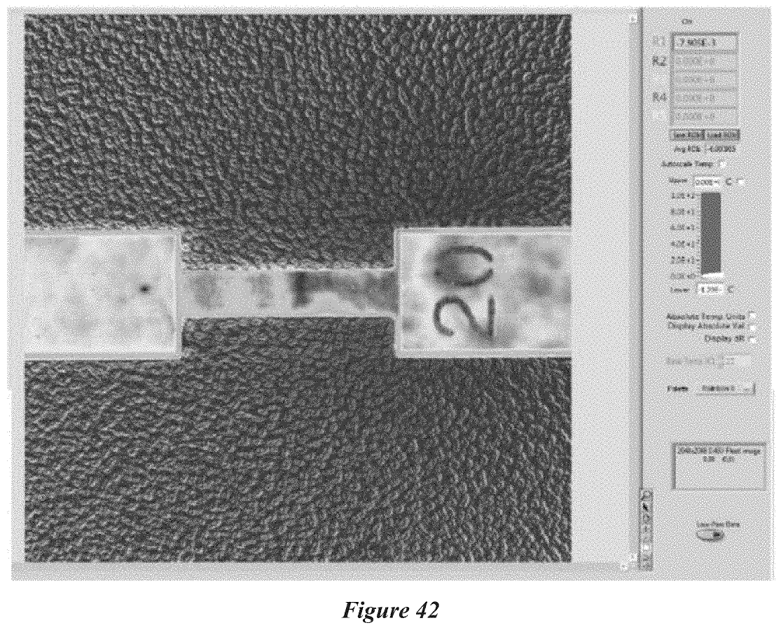

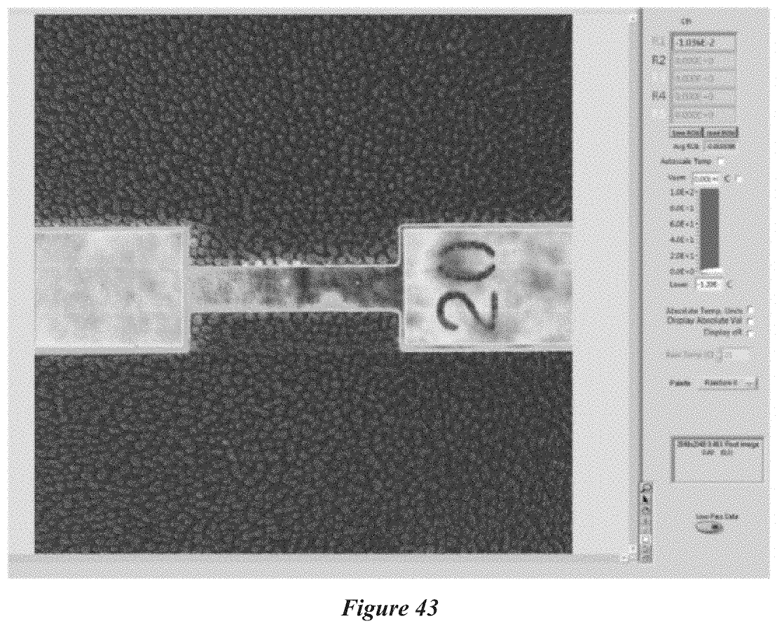

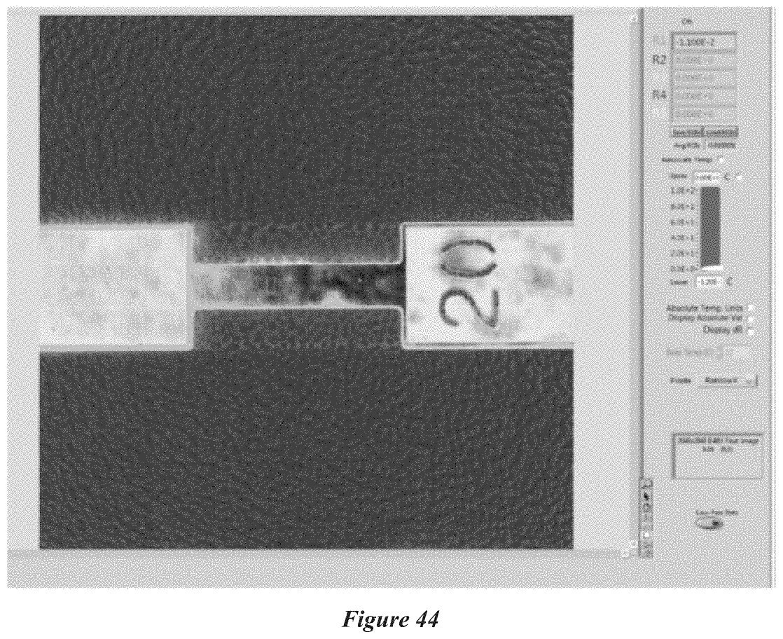

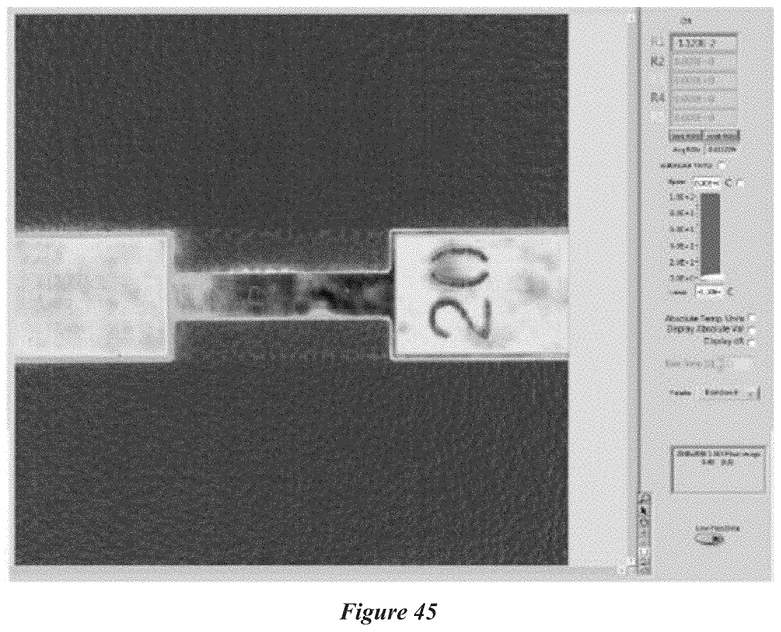

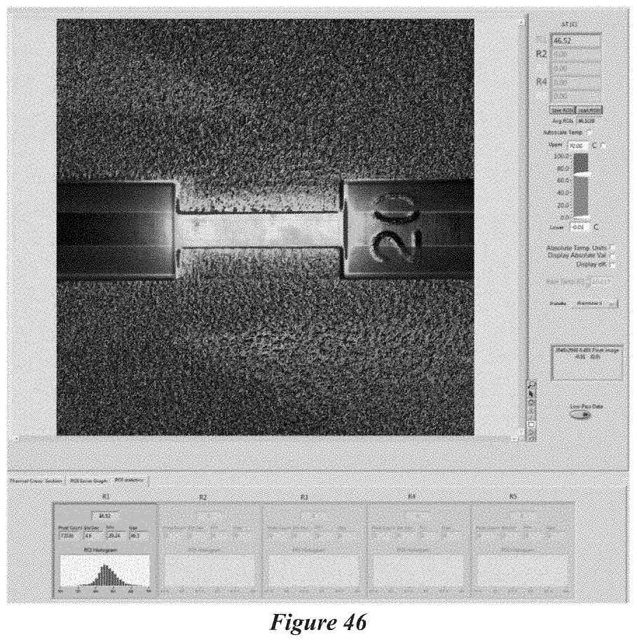

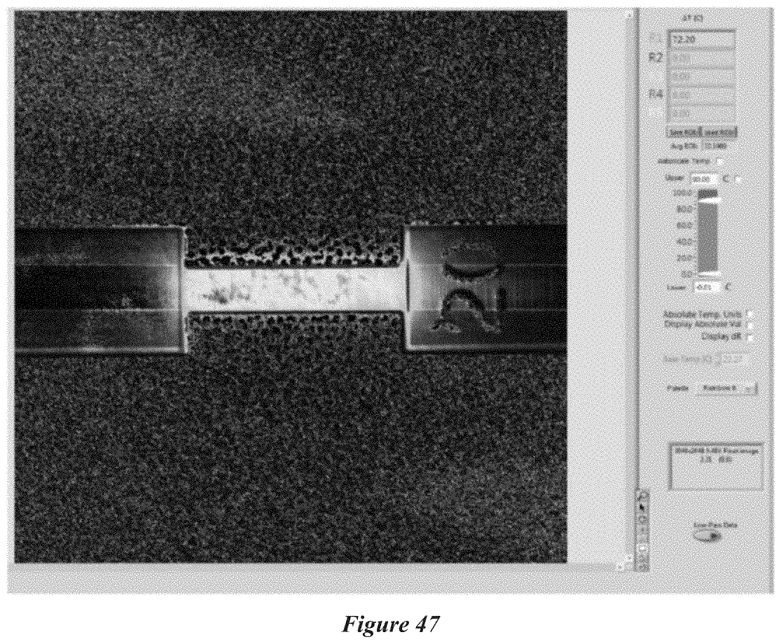

Uncoated measurements. The 20 μm TLM is shown up and to the right of the “+” sign in FIG. 40. Pulse information is shown in FIG. 41. TTI pulsed measurements were performed with a 20 μs LED delay time. TTI pulse series were performed with 5.4 μs LED delay time interval up to around 70 μs. Probes were lifted and temperature calibration was performed. Results at 100° C., 70° C., 60° C., and 50° C. are shown FIG. 42-FIG. 45, respectively. ΔR/R vs. T was fairly linear up to 70° C. Above that, it is non-linear. There is approximately <7% error due to non-linearity below 70° C., and a larger error due to non-linearity above 70° C. Thermal imaging of Device #1 is shown in FIG. 46.

The same pulse metrics were then used for Device #2. Thermal imaging of Device #2 is shown in FIG. 47. The results indicate that Device #2 is getting hotter than Device #1. The Cₜₕ of Device #2 is also lower than Device #1.

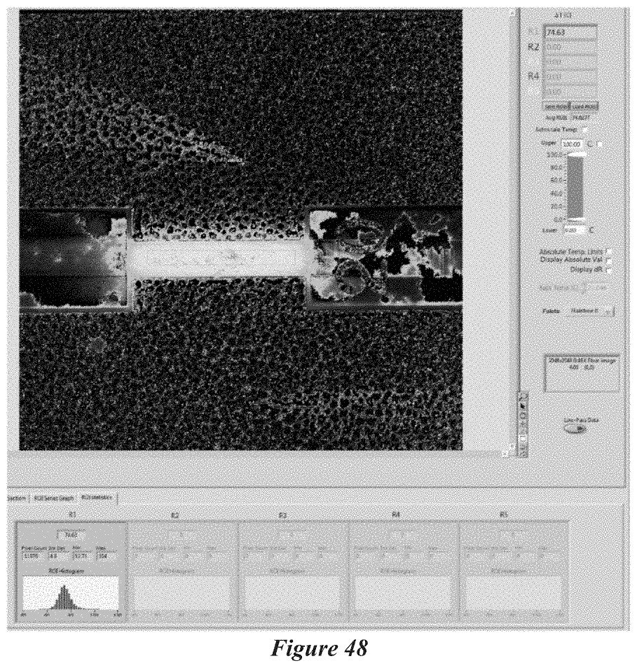

The same pulse metrics were then used for Device #3. Thermal imaging of Device #3 is shown in FIG. 48. The results for Device #3 agree well with Device #2, though the Cₜₕ of Device #3 is lower than for Device #2.

Coatings. For the coatings, Molylube was sonicated for 100 minutes. The sonication gives a good MoS₂ suspension. Immediately prior to drop coating, the suspension was sonicated for another 3 minutes. The devices were then coated with the Molylube using a gravity drop coating method. A drop of the Molylube suspension was placed on the device and dispersed over the area of interest using gravity.

Additional devices were coated using Sonal MoS₂/IPA/Tp using a drop coating method. A drop of the Sonal MoS₂/IPA/Tp was placed on the device and allowed to set. The Sonal MoS₂/IPA/Tp was a very thin solution, therefore gravity drop coating would not have deposited a sufficient coating.

Further devices were coated using Sonal MoS₂/IPA using a drop coating method. A drop of the Sonal MoS₂/IPA was placed on the device and allowed to set. The Sonal MoS₂/IPA was a very thin solution, therefore gravity drop coating would not have deposited a sufficient coating.

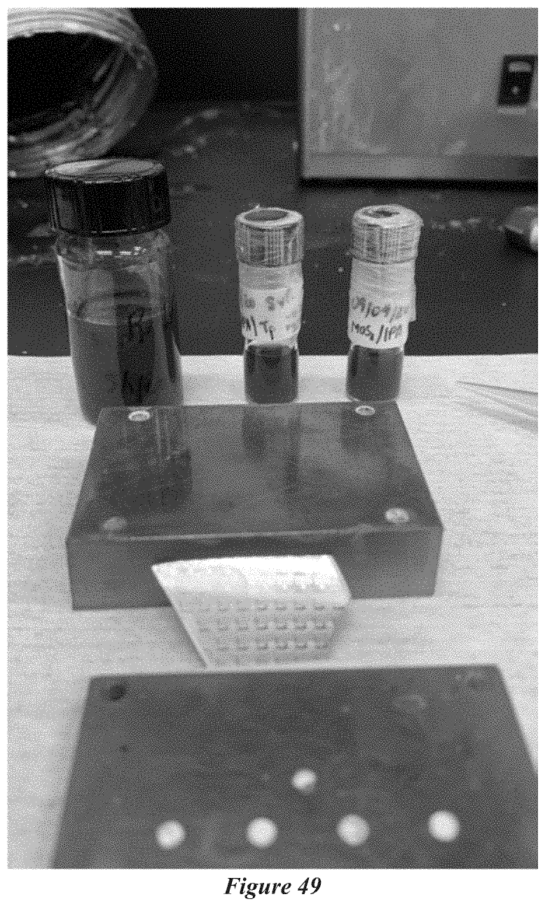

A photograph of the solutions used to coat the devices are shown in FIG. 49 (molylube, Sonal MoS₂/IPA/Tp, and Sonal MoS₂/IPA in vials left to right).

After the coatings were applied, the devices were placed in a vacuum oven at 120° C. A rough pump vacuum (24 inHg) was then applied. Subsequently, the vacuum oven was heated to 200° C. in 30 minutes. The furnace was then powered off and allowed to cool while leaving the vacuum on.

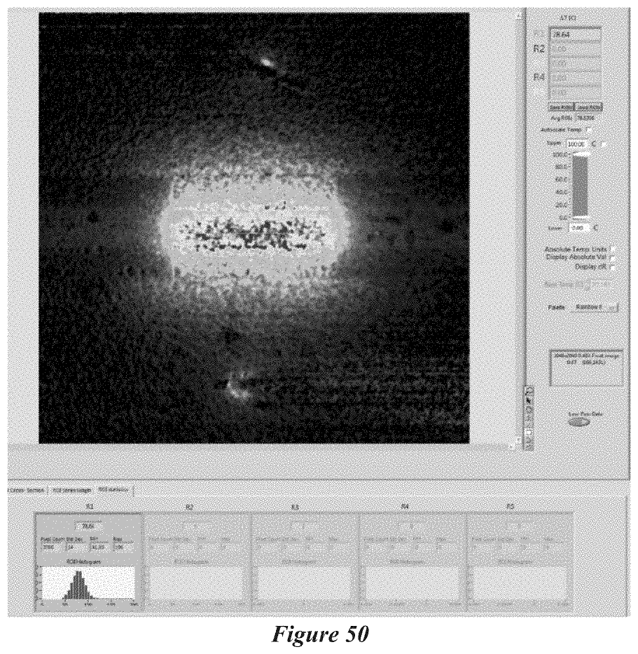

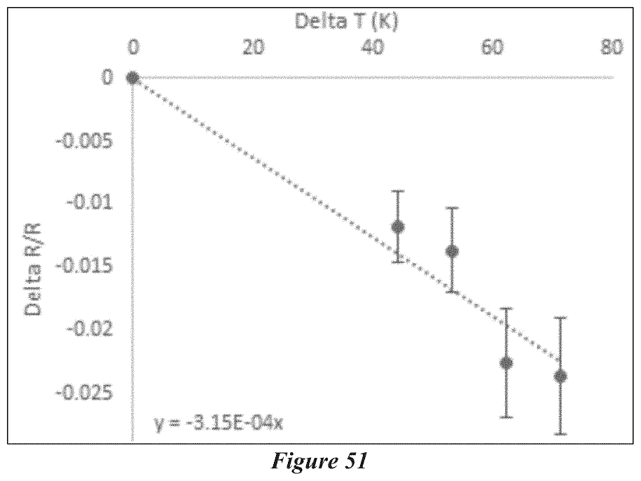

Coated measurements. TTI of sample coated with Molylube is shown in FIG. 50. Results indicate that the gravity drop coating method with the sonicated Molylube was successful. 4×4 binning and the low-pass filter helps with the standard deviation. However, the mean temperature value agrees with the uncoated map, regardless of data processing and filtering. A plot of ΔR/R vs. T is shown in FIG. 51.

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims. Since many possible embodiments may be made of the invention without departing from the scope thereof, it is to be understood that all matter herein set forth or shown in the accompanying drawings is to be interpreted as illustrative and not in a limiting sense.

The compositions, systems, and methods of the appended claims are not limited in scope by the specific compositions, system, and methods described herein, which are intended as illustrations of a few aspects of the claims and any methods that are functionally equivalent are intended to fall within the scope of the claims. Various modifications of the compositions, systems, and methods in addition to those shown and described herein are intended to fall within the scope of the appended claims. Further, while only certain representative composition elements, system elements, and method steps disclosed herein are specifically described, other combinations of the composition elements, system elements, and method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

What is claimed is:

1. A thermoreflectance coating comprising a transition metal dichalcogenide or a thermochromic polymer, wherein the thermoreflectance coating is an electrically resistive film that is reflective to one or more wavelengths of light from 400 nm to 1500 nm.

2. The coating of claim 1, wherein the coating has an average thickness of 10 nm to 1000 nm.

3. The coating of claim 1, wherein the coating has an average thickness of from 10 nm to 500 nm.

4. The coating of claim 1, wherein the coating has an average thickness of from 200 nm to 350 nm.

5. The coating of claim 1, wherein the coating comprises a transition metal dichalcogenide.

6. The coating of claim 5, wherein the transition metal dichalcogenide is selected from the group consisting of MoS₂, MoSe₂, WS₂, WSe₂, and combinations thereof.

7. The coating of claim 1, wherein the coating comprises a thermochromic polymer.

8. The coating of claim 7, wherein the thermochromic polymer comprises poly(ProDOT-alt-EDOT₂) (PE₂).

9. The coating of claim 1, wherein the coating has an average coefficient of thermoreflectance (Cₜₕ) of −2×10⁻⁴ K⁻¹ or less over a temperature range (ΔT) of 10 K or more.

10. The coating of claim 1. wherein the coating has an average coefficient of thermoreflectance (Cₜₕ) of −4×10⁻⁴ K⁻¹ or less over a temperature range (ΔT) of 10 K or more.

11. A method of enhancing the thermoreflectance of a wide bandgap semiconductor, the method comprising depositing the coating of claim 1 onto the wide bandgap semiconductor.

12. The method of claim 11, wherein depositing the coating comprises printing, spin coating, sputtering, electron beam deposition, drop-casting, or a combination thereof.

13. The method of claim 11, wherein the method further comprises forming a solution comprising a solvent and the transition metal dichalcogenide or thermochromic polymer, and depositing the mixture to form the coating.

14. The method claim 13, wherein forming the solution comprises dispersing the transition metal dichalcogenide or thermochromic polymer in the solvent.

15. The method of claim 11, wherein the method further comprising drying the coating after depositing the coating.

16. A device comprising a wide handgap or ultrawide handgap semiconductor, wherein the device further comprises the coating of claim 1 deposited on the wide bandgap or ultrawide bandgap semiconductor.

17. The device of claim 16, wherein the coating does not significantly impact the operation of the device.

18. A method of thermally imaging a wide bandgap ultrawide bandgap semiconductor, the method comprising depositing the coating of claim 1 on the wide bandgap or ultrawide bandgap semiconductor and thermally imaging the coating.

19. The method of claim 18, wherein the coating is thermally imaging using transient thermoreflectance imaging.

20. The method of claim 18, wherein the method uses a probe light having a wavelength below the bandgap of the semiconductor and being reflective to the coating.
